(19) United States
(12) Patent Application Publication
(10) Pub. No.: US 2025/0112145 A1
(43) Pub. Date: Apr. 3, 2025

(54) METHODS AND APPARATUS TO IMPROVE INTERCONNECT STRUCTURES IN INTEGRATED CIRCUIT PACKAGES

(71) Applicant: Intel Corporation, Santa Clara, CA (US)

(72) Inventors: Aleksandar Aleksov, Chandler, AZ (US); Tushar Kanti Talukdar, Wilsonville, OR (US)

(21) Appl. No.: 18/478,529

(22) Filed: Sep. 29, 2023

(51) Int. Cl. H01L 23/522; H01L 21/768; H01L 23/532

(52) U.S. Cl. CPC H01L 23/5226; H01L 21/7682; H01L 21/76837; H01L 21/76885; H01L 23/5329

(57) ABSTRACT

Methods and apparatus are disclosed to improve interconnect structures in integrated circuit packages. An example integrated circuit (IC) package includes a first interconnect structure positioned on a first surface of an underlying substrate; a second interconnect structure positioned on the first surface of the underlying substrate, the second interconnect structure adjacent to the first interconnect structure; and a first dielectric material between the first and second interconnect structures, the first dielectric material including an enclosed trench within a space between the first and second interconnect structures.

### FIELD OF THE DISCLOSURE

This disclosure relates generally to integrated circuits and, more particularly, to methods and apparatus to improve interconnect structures in integrated circuit packages.

### BACKGROUND

In many integrated circuit (IC) packages, one or more semiconductor dies are mechanically and electrically coupled to an underlying package substrate. During an IC fabrication process, devices (e.g., transistors, capacitors, etc.) within the semiconductor die are interconnected. Further, the die is typically mounted to a package substrate that enables the die to be connected to a printed circuit board and/or other electrical components. As integrated circuit (IC) chips and/or dies reduce in size and interconnect densities increase, alternatives to traditional interconnects within the dies themselves as well interconnects within package substrates supporting such dies are needed for providing stable transmission of high frequency data signals between different circuitry and/or increased power delivery.

### BRIEF DESCRIPTION OF THE DRAWINGS

FIG. 1 is a top view of a wafer including dies that may be constructed in accordance with teachings disclosed herein.

FIG. 2 is a cross-sectional side view of an example IC device that may be included in an IC package constructed in accordance with teachings disclosed herein.

FIG. 3 is a cross-sectional side view of an IC package that may include an IC device in accordance with teachings disclosed herein.

FIG. 4 is a cross-sectional side view of an IC device assembly that may include an IC package constructed in accordance with teachings disclosed herein.

FIG. 5 is a cross-sectional side view of another example IC device including example dielectric structures constructed in accordance with teachings disclosed herein.

FIG. 6 is a cross-sectional side view of the example IC device of FIG. 5 after a second dielectric layer including dielectric structures has been added.

FIG. 7 is an enlarged portion of the cross-sectional side view of the example IC device and dielectric structures of FIGS. 5 and 6.

FIG. 8 is a cross-sectional side view of another example IC device having an example dielectric structure disclosed herein.

FIG. 9 is a schematic illustration of another example IC device having an example dielectric structure disclosed herein.

FIGS. 10A-10D illustrate various stages of manufacture of the example dielectric structures of FIGS. 5-9.

FIGS. 11A-11C illustrate various stages of manufacture of the example dielectric structures of FIGS. 5-9.

FIGS. 12A-12D illustrate various stages of manufacture of an example dielectric structure of FIGS. 5-9.

FIG. 13 is a cross-sectional side this view of another example IC device having example dielectric structures disclosed herein.

FIGS. 14A-14D illustrate various stages of manufacture of the example dielectric structures of FIG. 13.

FIG. 15 is a flowchart representing an example manufacturing process for manufacturing the example package substrate and the example dielectric structures disclosed herein.

FIG. 16 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein “substantially real time” refers to occurrence in a near instantaneous manner recognizing there may be real world delays for computing time, transmission, etc. Thus, unless otherwise specified, “substantially real time” refers to real time+1 second.

As used herein, “substantially vertically” or “substantially perpendicular” means perfectly vertical or perpendicular or within +/−5 degrees of perfectly vertical or perpendicular. As used herein, “substantially horizontally” or “substantially parallel” means perfectly parallel or horizontal or within +/−5 degrees of perfectly horizontal or parallel.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

### DETAILED DESCRIPTION

Electrical signals, such as power and/or input/output (I/O) signals, may be routed to and/or from devices (e.g., transistors, etc.) of a semiconductor die through one or more interconnect layers. Typically, the interconnect layers include an insulating or dielectric material disposed between the interconnect structures. For example, the interconnect structures can include conductive material (e.g., lithographically patterned) defining traces, pads, and the like in metal layers between adjacent dielectric layers. Further, the interconnect structures can include conductive vias traversing through the dielectric layers to electrically couple different ones of the metal layers. The traces and associated vias define electrical wiring (e.g., signaling lines) to transfer signals or information between various components (e.g., transistors, capacitors, resistors, backend layers, etc. and/or other circuitry) of the semiconductor package and/or power traces for transferring or carrying power to the various components of the semiconductor package. The interconnect structures are arranged to route the electrical signals according to a wide variety of designs.

In low-loss, high bandwidth, high density interconnect substrates, increased power delivery and signaling requirements require dense signaling process areas. As electronic systems become more complex and electrical interfaces in the electrical systems operate at higher frequencies, dense signal processing areas can cause significant crosstalk or unwanted signal cross-over between adjacent signal paths in such densely packed spaces. For example, crosstalk may be noise induced by one signal that interferes with another signal, which reduces the performance of an IC package (e.g., within the semiconductor die in the IC package and/or within a package substrate of the IC package). Crosstalk between conductive layers of the IC package (e.g., within a die and/or within a package substrate supporting the die) can limit the bandwidth of data that can be transmitted through the IC package.

An amount of crosstalk between the interconnects is at least partially dependent on a dielectric material (e.g., inter-metal dielectric) used in the dielectric layers. Each dielectric material is associated with a dielectric constant (k) or relative permittivity (ε). As used herein, a material's k-value refers to a dielectric constant(s) associated with that material. In some examples, a relatively high dielectric constant (k) (e.g., a dielectric constant above 2) is associated with higher capacitive coupling between interconnect structures and, consequently, increased levels of crosstalk. Thus, inter-metal dielectric materials are often selected for low capacitance to improve signal routing. Efforts to reduce a dielectric constant of a dielectric filling in spaces between interconnect structures is important for increasing signal bandwidth for a dense bundle of traces by reducing crosstalk between the traces.

Typically filled and/or unfilled organic dielectric materials are used for wafer-level and panel-level packaging (e.g., a substrate package(s), an organic interposer(s), a redistribution layer(s) (RDL), etc.). In many instances, polymer dielectric materials are used during signal routing, some of which are filled with silica to adjust the mechanical properties of the polymer dielectric material. Silica-filled dielectric materials are associated with dielectric constants ranging from approximately 2.0 to 3.4. When used as an inter-metal dielectric, certain dielectric materials result in undesired levels of metal capacitive coupling and crosstalk issues. For filled dielectric materials, such as dry and liquid buildup films, a major contributor to its dielectric constant is the silica (also known as silicon dioxide) filler. This is in part because silicon is associated with a relatively high dielectric constant. For example, silicon dioxide (SiO2) is a common dielectric, and has a dielectric constant of approximately 3.9. In some examples, hollow fillers are used to lower the dielectric constant associated with these films. However, buildup films having hollow fillers cause concerns regarding filler reliability. For example, the fillers can crack. In some examples, the hollow cavity inside can collapse due to mechanical stresses and/or pressure during manufacturing and/or use.

Unfilled dielectric materials are associated with dielectric constants ranging from approximately 2.5 to 3.0. For example, polyimide-based (PI-based) dielectrics are associated with dielectric constants ranging from approximately 2.8 to 3.0. To lower the dielectric constants further, fluorinated monomers can be used to create the polymers. This may lower the dielectric constants to approximately 2.0 to 2.3. However, unfilled organic materials are typically associated with a high coefficient of thermal expansion (CTE). For example, a CTE for unfilled organic materials is approximately 2.5 times to 4 times higher than for copper. This mismatch between the interconnect structures (typically made of copper) and the dielectric material causes significant stresses at low copper density vias, necessitating large vias to survive repeated thermal stresses (e.g., thermal cycling) without cracking or otherwise being disconnected from the interconnect structure(s) below and/or above (e.g., typically the via bottom cracks due to the tapered nature of vias in PI-based dielectrics). Fluorinating the organic dielectric leads to larger issues as the CTE typically grows. For instance, a fluorinated material such as Teflon is associated with a CTE larger than 100 parts per million (ppm) per degree Celsius (C) (ppm/° C.). Further, adhesion properties of the polymer typically degrade with the degree of fluorination.

In some examples, carbon-doped oxides (CDO) or dielectrics with a given porosity are used to reduce a dielectric constant of an inter-metal dielectric. For example, CDO materials can be used in semiconductor damascene interconnects, such as used in silicon interposers or silicon bridges, to obtain a lower dielectric constant. In some examples, CDOs or dielectrics with a given porosity are used, which are associated with a dielectric constant of approximately 2.6. However, such dielectric constants are relatively high (e.g., greater than 2), resulting in undesired levels of parasitic capacitance and crosstalk.

A vacuum provides a substantially lower dielectric constant, closely followed by air, which is associated with a dielectric constant of approximately 1. In some examples, process integration schemes for dual-damascene interconnects allow for the generation of pockets of air or airgaps (also referred to herein as voids, trenches, and openings) between adjacent interconnect structures to reduce a dielectric constant between the interconnect structures. However, these processes cannot be used for die-to-die (D2D) or Tile-to-Tile (e.g., Chiplet-to-Chiplet) interconnects. Further, creating an air-gap dielectric using dual-damascene processing is expensive as it requires additional process steps, masks, barrier layers, and cure steps as well as sacrificial materials. Moreover, the placement of air gaps compromises the mechanical stability of the integrated circuit making it impractical to build an IC composed substantially or entirely of air as the insulating material.

As integrated circuit (IC) chips and/or dies reduce in size and interconnect densities increase, alternatives to traditional dielectric materials are needed for providing stable transmission of high frequency data signals between different circuitry and/or increased power delivery.

Example dielectric structures and methods of manufacturing the same are disclosed herein. Examples disclosed herein enable a dielectric structure having a relatively low dielectric constant (e.g., a dielectric constant less than approximately 2). Example dielectric structures disclosed herein include a first dielectric material that surrounds or otherwise encloses a second dielectric material. The first dielectric material is associated with a first dielectric constant that is higher than a second dielectric material associated with the second dielectric material. In some examples, the second dielectric material is air. In particular, examples disclosed herein enable fabrication of a dielectric structure having an airgap. By combining this airgap with the first dielectric material, the example dielectric structure disclosed herein is associated with a dielectric constant that is lower relative to that of a space filled with the first dielectric material.

Example dielectric structures disclosed herein include airgaps that are enclosed by the first dielectric material. In particular, after a planarization process and/or an etching process (e.g., to reveal a via) of a dielectric layer containing such dielectric structures, the resulting (e.g., exposed) exterior surfaces of the dielectric layer remain closed off such that the airgaps remain contained in (e.g., surrounded by) the material of the dielectric layer. As such, a subsequent layer can be processed directly onto the dielectric layer containing the airgaps without the need for additional hard-masks, barriers, curing, and/or outgassing. In other words, examples disclosed herein enable stacking two or more layers having airgaps no more costly or complex than creating layers without airgaps.

Example dielectric structures disclosed herein can be integrated between metal lines (e.g., traces) to reduce cross and/or capacitive coupling. In particular, disclosed examples enable fabrication of example dielectric structures between adjacent interconnect structures. Certain examples enable an increase of bandwidth provided by a semiconductor die and/or an IC device.

Example dielectric structures disclosed herein can be used adjacent to or on a glass core to enable highest signaling per line applications and/or lowest losses for critical interconnects. For high speed input/output (HSIO) interconnects, example interconnect structures do not need to be roughened to achieve good adhesion to the solid-state dielectric material of example dielectric structures disclosed herein. This further increases or improves bandwidth advantage of these interconnect structures, especially when compared to current redistribution layers (e.g., current wafer-level package solutions).

Example dielectric structures disclosed herein are compatible with hybrid bonding processes. This is an advantage with respect to currently used organic interposers or interconnect layers that degrade significantly when exposed to prolonged temperatures required for hybrid bonding.

Example dielectric structures disclosed herein reduce or eliminate copper migration issues because ion migration paths are reduced due to the presence of the airgap. Examples disclosed herein enable cost efficient dielectric structures, even for dielectric layers in the 4-10 μm thick (e.g., for high density high-bandwidth D2D or Tile-2-Tile interconnectivity). Examples disclosed herein can be utilized in HSIO signaling using approximately 40 μm thick dielectric layers (e.g., 15 μm trace, 25 μm via, etc.).

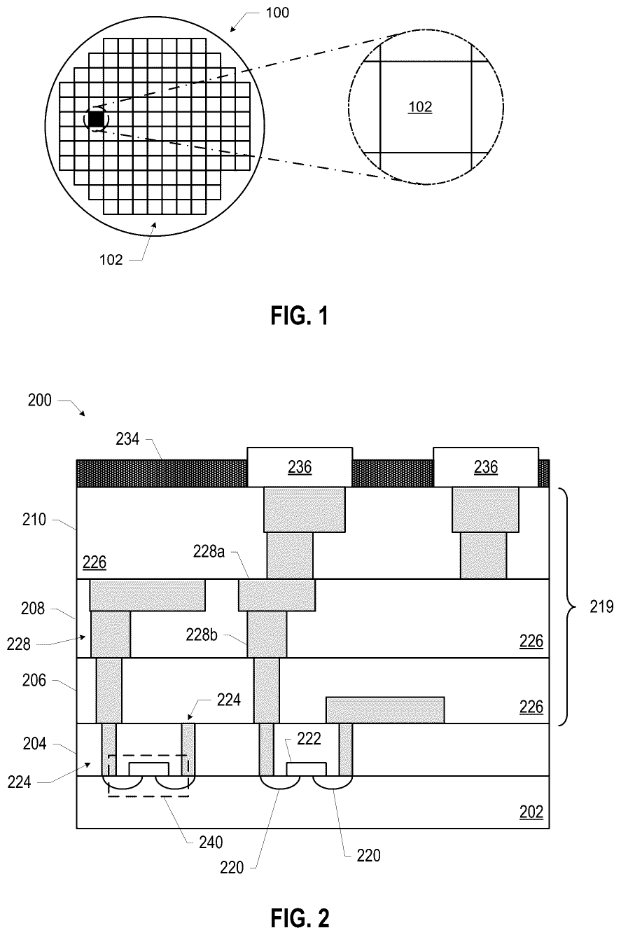

FIG. 1 is a top view of a wafer 100 and dies 102 that may be included in an IC package constructed in accordance with teachings disclosed herein. The wafer 100 may be composed of semiconductor material and may include one or more dies 102 having circuitry. Each of the dies 102 may be a repeating unit of a semiconductor product. After the fabrication of the semiconductor product is complete, the wafer 100 may undergo a singulation process in which the dies 102 are separated from one another to provide discrete “chips.” The die 102 may include one or more transistors (e.g., some of the transistors 240 of FIG. 2, discussed below), supporting circuitry to route electrical signals to the transistors, passive components (e.g., traces, resistors, capacitors, inductors, and/or other circuitry), and/or any other components.

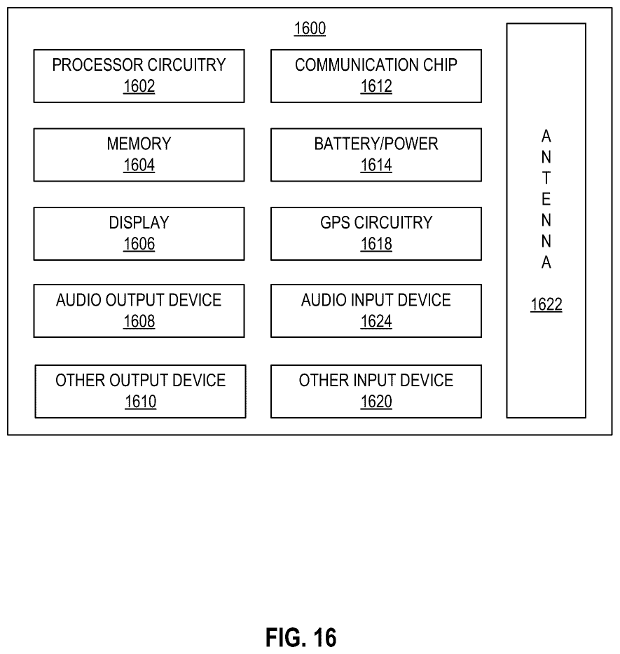

In some examples, the die 102 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die 102. For example, a memory array formed by multiple memory circuits may be formed on a same die 102 as programmable circuitry (e.g., the processor circuitry 1602 of FIG. 16) or other logic circuitry. Such memory may store information for use by the programmable circuitry.

FIG. 2 is a cross-sectional side view of an IC device 200 that may be included in an IC package constructed in accordance with teachings disclosed herein. One or more of the IC devices 200 may be included in one or more dies 102 (FIG. 1). The IC device 200 may be formed on a die substrate 202 (e.g., the wafer 100 of FIG. 1) and may be included in a die (e.g., the die 102 of FIG. 1). The die substrate 202 may be a semiconductor substrate composed of semiconductor material systems including, for example, n-type or p-type materials systems (or a combination of both). The die substrate 202 may include, for example, a crystalline substrate formed using a bulk silicon or a silicon-on-insulator (SOI) substructure. In some examples, the die substrate 202 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 202. Although a few examples of materials from which the die substrate 202 may be formed are described here, any material that may serve as a foundation for an IC device 200 may be used. The die substrate 202 may be part of a singulated die (e.g., the dies 102 of FIG. 1) or a wafer (e.g., the wafer 100 of FIG. 1).

The IC device 200 may include a device layer(s) 204 disposed on or above the die substrate 202. The device layer 204 may include features of one or more transistors 240 (e.g., metal oxide semiconductor field-effect transistors (MOSFETs)) formed on the die substrate 202. The device layer 204 may include, for example, one or more source and/or drain (S/D) regions 220, a gate 222 to control current flow between the S/D regions 220, and one or more S/D contacts 224 to route electrical signals to/from the S/D regions 220. The transistors 240 may include additional features not depicted for the sake of clarity, such as device isolation regions, gate contacts, and the like. The transistors 240 are not limited to the type and configuration depicted in FIG. 2 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 240 may include a gate 222 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 240 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 240 along the source-channel-drain direction, the gate electrode may include a U-shaped structure that includes a bottom portion substantially parallel to the surface of the die substrate 202 and two sidewall portions that are substantially perpendicular to the top surface of the die substrate 202. In other examples, at least one of the metal layers that form the gate electrode may simply be a planar layer that is substantially parallel to the top surface of the die substrate 202 and does not include sidewall portions substantially perpendicular to the top surface of the die substrate 202. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 220 may be formed within the die substrate 202 adjacent to the gate 222 of each transistor 240. The S/D regions 220 may be formed using an implantation/diffusion process or an etching/deposition process, for example. In the former process, dopants such as boron, aluminum, antimony, phosphorous, or arsenic may be ion-implanted into the die substrate 202 to form the S/D regions 220. An annealing process that activates the dopants and causes them to diffuse farther into the die substrate 202 may follow the ion-implantation process. In the latter process, the die substrate 202 may first be etched to form recesses at the locations of the S/D regions 220. An epitaxial deposition process may then be carried out to fill the recesses with material that is used to fabricate the S/D regions 220. In some implementations, the S/D regions 220 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 220 may be formed using one or more alternate semiconductor materials such as germanium or a group III-V material or alloy. In further examples, one or more layers of metal and/or metal alloys may be used to form the S/D regions 220.

Electrical signals, such as power and/or input/output (I/O) signals, may be routed to and/or from the devices (e.g., transistors 240) of the device layer 204 through one or more interconnect layers disposed on the device layer 204 (illustrated in FIG. 2 as interconnect layers 206-210). For example, electrically conductive features of the device layer 204 (e.g., the gate 222 and the S/D contacts 224) may be electrically coupled with the interconnect structures 228 of the interconnect layers 206-210. The one or more interconnect layers 206-210 may form a metallization stack (also referred to as an “ILD stack”) 219 of the IC device 200.

The interconnect structures 228 may be arranged within the interconnect layers 206-210 to route electrical signals according to a wide variety of designs (in particular, the arrangement is not limited to the particular configuration of interconnect structures 228 depicted in FIG. 2). In other words, the interconnect structures 228 show routing that may be manufactured during a BEOL process. Although a particular number of interconnect layers 206-210 is depicted in FIG. 2, examples of the present disclosure include IC devices having more or fewer interconnect layers than depicted.

In some examples, the interconnect structures 228 may include traces 228a (e.g., lines, interconnect wires, metal layers, etc.) and/or vias 228b (e.g., conductive vias, electrical vias, etc.). The traces 228a may be arranged to route electrical signals in a direction of a plane that is substantially parallel with a surface of the die substrate 202 upon which the device layer 204 is formed. For example, the traces 228a may route electrical signals in a direction in and out of the page from the perspective of FIG. 2. The traces 228a of the illustrated example define signal traces (e.g., signaling lines) to transfer signals or information between various components (e.g., transistors, capacitors, resistors, backend layers, etc. and/or other circuitry) of the IC device 200 and/or power traces for transferring or carrying power to the various components of the IC device 200. The vias 228b may be arranged to route electrical signals in a direction of a plane that is substantially perpendicular to the surface of the die substrate 202 upon which the device layer 204 is formed. In some examples, the vias 228b may electrically couple traces 228a of different interconnect layers 206-210 together.

The interconnect layers 206-210 may include a dielectric material 226 (e.g., an inter-metal dielectric material) disposed between the interconnect structures 228, as shown in FIG. 2. In some examples, the dielectric material 226 disposed between the interconnect structures 228 in different ones of the interconnect layers 206-210 may have different compositions. In other examples, the composition of the dielectric material 226 between different interconnect layers 206-210 may be the same. In some examples, an interconnect layer 206-210 can include multiple layers of the dielectric material 226 between adjacent ones of the metal layers associated with metal interconnect structures 228. That is, in some examples, the vias 228b extend through multiple layers of the dielectric material. In some examples, the dielectric material 226 provides electrical insulation between the interconnect structures 228. The dielectric material 226 may be selected such that the dielectric material 226 prevents or otherwise reduces electrical coupling between ones of the interconnect structures 228. In some examples, the dielectric material 226 in one or more of the interconnect layers 206-210 includes example dielectric structures associated with airgaps as discussed further herein. In some examples, the dielectric structures and associated air gaps are positioned between adjacent ones of the interconnect structures 228.

A first interconnect layer 206 (referred to as Metal 1 or “M1”) may be formed directly on the device layer 204. In some examples, the first interconnect layer 206 may include traces 228a and/or vias 228b, as shown. The traces 228a of the first interconnect layer 206 may be coupled with contacts (e.g., the S/D contacts 224) of the device layer 204.

A second interconnect layer 208 (referred to as Metal 2 or “M2”) may be formed directly on the first interconnect layer 206. In some examples, the second interconnect layer 208 may include vias 228b to couple the traces 228a of the second interconnect layer 208 with the traces 228a of the first interconnect layer 206. Although the traces 228a and the vias 228b are structurally delineated with a line within each interconnect layer (e.g., within the second interconnect layer 208) for the sake of clarity, the traces 228a and the vias 228b may be structurally and/or materially contiguous (e.g., simultaneously filled during a dual-damascene process) in some examples.

A third interconnect layer 210 (referred to as Metal 3 or “M3”) (and additional interconnect layers, as desired) may be formed in succession on the second interconnect layer 208 according to similar techniques and configurations described in connection with the second interconnect layer 208 or the first interconnect layer 206. In some examples, the interconnect layers that are “higher up” in the metallization stack 219 in the IC device 200 (i.e., further away from the device layer 204) may be thicker.

The IC device 200 may include a solder resist material 234 (e.g., polyimide or similar material) and one or more conductive contacts 236 formed on the interconnect layers 206-210. In FIG. 2, the conductive contacts 236 are illustrated as taking the form of bond pads. The conductive contacts 236 may be electrically coupled with the interconnect structures 228 and configured to route the electrical signals of the transistor(s) 240 to other external devices. For example, solder bonds may be formed on the one or more conductive contacts 236 to mechanically and/or electrically couple a chip including the IC device 200 with another component (e.g., a circuit board). The IC device 200 may include additional or alternate structures to route the electrical signals from the interconnect layers 206-210; for example, the conductive contacts 236 may include other analogous features (e.g., posts) that route the electrical signals to external components.

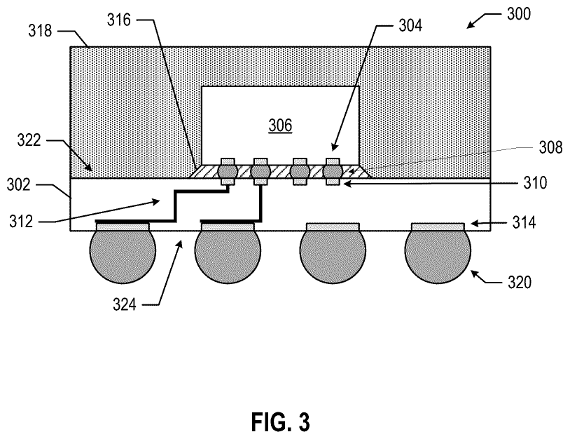

FIG. 3 is a cross-sectional view of an example IC package 300 that may include an IC device(s) 200 (FIG. 2), one or more dies 102 (FIG. 1), and/or other semiconductor devices constructed in accordance with teachings of this disclosure. The IC package 300 includes a package substrate 302. The package substrate 302 may be formed of a dielectric material, and may have conductive pathways extending through the dielectric material between first (e.g., upper) and second (e.g., lower faces) 322, 324, or between different locations on the upper face 322, and/or between different locations on the lower face 324. These conductive pathways may take the form of any of the interconnects 228 discussed above with reference to FIG. 2.

The IC package 300 may include a die 306 coupled to the package substrate 302 via conductive contacts 304 of the die 306, first-level interconnects 308, and conductive contacts 310 of the package substrate 302. The conductive contacts 310 may be coupled to conductive pathways 312 through the package substrate 302, allowing circuitry within the die 306 to electrically couple to various ones of the conductive contacts 314 or to other devices included in the package substrate 302, not shown. The first-level interconnects 308 illustrated in FIG. 3 are solder bumps, but any suitable first-level interconnects 308 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

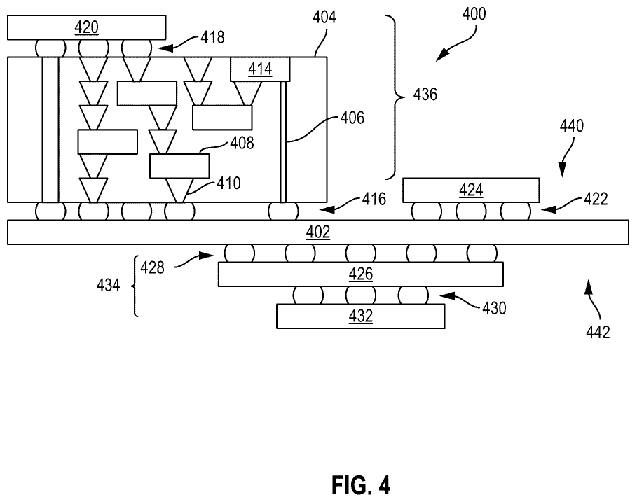

In some examples, an underfill material 316 may be disposed between the die 306 and the package substrate 302 around the first-level interconnects 308, and a mold compound 318 may be disposed around the die 306 and in contact with the package substrate 302. In some examples, the underfill material 316 may be the same as the mold compound 318. Example materials that may be used for the underfill material 316 and the mold compound 318 are epoxy mold materials, as suitable. Second-level interconnects 320 may be coupled to the conductive contacts 314. The second-level interconnects 320 illustrated in FIG. 3 are solder balls (e.g., for a ball grid array arrangement), but any suitable second-level interconnects 320 may be used (e.g., pins in a pin grid array arrangement or lands in a land grid array arrangement). The second-level interconnects 320 may be used to couple the IC package 300 to another component, such as a circuit board (e.g., a motherboard), an interposer, or another IC package, as known in the art and as discussed below with reference to FIG. 4.

In FIG. 3, the IC package 300 is a flip chip package. Although the IC package 300 illustrated in FIG. 3 is a flip chip package, other package architectures may be used. For example, the IC package 300 may be a ball grid array (BGA) package, such as an embedded wafer-level ball grid array (eWLB) package. In another example, the IC package 300 may be a wafer-level chip scale package (WLCSP) or a panel fanout (FO) package.

The die 306 may take the form of any of the examples of dies discussed herein (e.g., may include any of the examples of the die 102, the IC device 200, etc.). In some examples, the IC package 300 includes example dielectric structure(s) associated with airgap(s) between interconnect structures as discussed further herein. In some examples, the dielectric structures are implemented in the example die 306 of the IC package 300. For example, the die 306 can include one or more of the interconnect layers having interconnect structures (e.g., electrical routing) with example dielectric structures associated with airgaps disposed between different conductive traces and/or vias as discussed further herein. Additionally or alternatively, in some examples, the dielectric structures are implemented in the package substrate 302 of the example IC package 300. For example, the package substrate 302 can include conductive layers defining electrical routing (e.g., traces) interconnected by vias extending between different conductive layers to define the pathways 312 with example dielectric structures associated with airgaps disposed between different the traces and/or vias as discussed further herein.

Although a single die 306 is illustrated in the IC package 300 of FIG. 3, an IC package 300 may include multiple dies 306. An IC package 300 may include additional passive components, such as surface-mount resistors, capacitors, and inductors disposed on the first (upper) face 322 or the second (lower) face 324 of the package substrate 302. More generally, an IC package 300 may include any other active or passive components known in the art.

FIG. 4 is a cross-sectional side view of an IC device assembly 400 that may include the example dielectric structures associated with airgaps as discussed further herein. The IC device assembly 400 includes a number of components disposed on a circuit board 402 (which may be, for example, a motherboard). The IC device assembly 400 includes components disposed on a first face 440 of the circuit board 402 and an opposing second face 442 of the circuit board 402. Generally, the components may be disposed on one or both faces 440 and 442.

In some examples, the circuit board 402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 402. In other examples, the circuit board 402 may be a non-PCB substrate.

The IC device assembly 400 illustrated in FIG. 4 includes a package-on-interposer structure 436 coupled to the first face 440 of the circuit board 402 by coupling components 416. The coupling components 416 may electrically and mechanically couple the package-on-interposer structure 436 to the circuit board 402, and may include solder balls (as shown in FIG. 4), male and female portions of a socket, an adhesive, an underfill material, and/or any other suitable electrical and/or mechanical coupling structure.

The package-on-interposer structure 436 may include an IC package 420 coupled to an interposer 404 by coupling components 418. The coupling components 418 may take any suitable form for the application, such as the forms discussed above with reference to the coupling components 416. Although a single IC package 420 is shown in FIG. 4, multiple IC packages may be coupled to the interposer 404. Indeed, additional interposers may be coupled to the interposer 404. The interposer 404 may provide an intervening substrate used to bridge the circuit board 402 and the IC package 420. The IC package 420 may be or include, for example, a die (the die 102 of FIG. 1), an IC device (e.g., the IC device 200 of FIG. 2, etc.), or any other suitable component. Generally, the interposer 404 may spread a connection to a wider pitch or reroute a connection to a different connection. For example, the interposer 404 may couple the IC package 420 (e.g., a die) to a set of BGA conductive contacts of the coupling components 416 for coupling to the circuit board 402. In the example illustrated in FIG. 4, the IC package 420 and the circuit board 402 are attached to opposing sides of the interposer 404. In other examples, the IC package 420 and the circuit board 402 may be attached to a same side of the interposer 404. In some examples, three or more components may be interconnected by way of the interposer 404.

In some examples, the interposer 404 may be formed as a PCB, including multiple metal layers separated from one another by layers of dielectric material and interconnected by electrically conductive vias. In some examples, the interposer 404 may be formed of an epoxy resin, a fiberglass-reinforced epoxy resin, an epoxy resin with inorganic fillers, a ceramic material, or a polymer material such as polyimide. In some examples, the interposer 404 may be formed of alternate rigid or flexible materials that may include the same materials described above for use in a semiconductor substrate, such as silicon, germanium, and other group III-V and group IV materials. The interposer 404 may include metal interconnects 408 and vias 410, including but not limited to through-silicon vias (TSVs) 406. The dielectric material may be selected to prevent or otherwise reduce electrical coupling between ones of the metal interconnect 408, the TSVs 406, and/or the vias 410. In some examples, the dielectric material in one or more of the includes example dielectric structures associated with airgaps as discussed further herein. In some examples, the dielectric structures and associated air gaps are positioned between adjacent ones of the metal interconnect 408, the TSVs 406, and/or the vias 410.

The interposer 404 may further include embedded devices 414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 404. The package-on-interposer structure 436 may take the form of any of the package-on-interposer structures known in the art.

The IC device assembly 400 may include an IC package 424 coupled to the first face 440 of the circuit board 402 by coupling components 422. The coupling components 422 may take the form of any of the examples discussed above with reference to the coupling components 416, and the IC package 424 may take the form of any of the examples discussed above (e.g., the IC package 300 of FIG. 3) or below (e.g., first IC package 426, second IC package 432, etc.) with reference to the IC package 420.

The IC device assembly 400 illustrated in FIG. 4 includes a package-on-package structure 434 coupled to the second face 442 of the circuit board 402 by coupling components 428. The package-on-package structure 434 may include a first IC package 426 and a second IC package 432 coupled together by coupling components 430 such that the first IC package 426 is disposed between the circuit board 402 and the second IC package 432. The coupling components 428, 430 may take the form of any of the examples of the coupling components 416 discussed above, and the IC packages 426, 432 may take the form of any of the examples of the IC package 420 discussed above. The package-on-package structure 434 may be configured in accordance with any of the package-on-package structures known in the art.

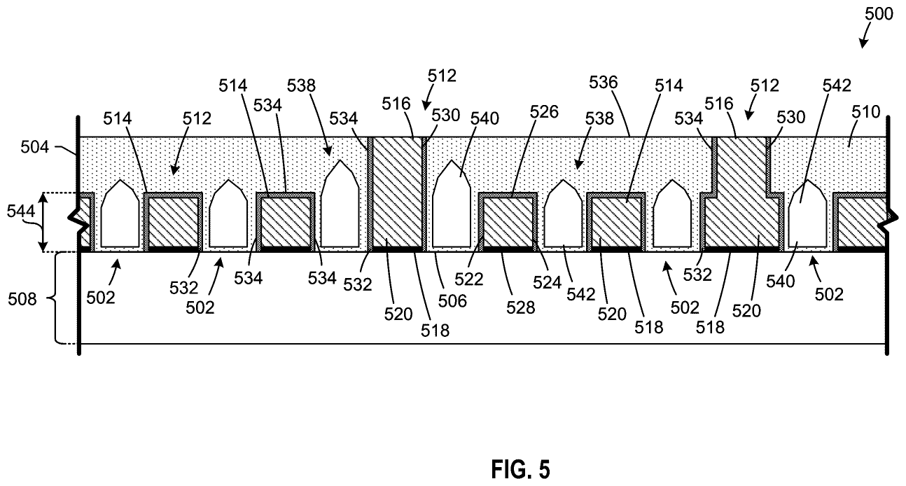

FIG. 5 is a cross sectional side view of a portion of another example IC device 500 including example dielectric structures 502 provided within a first interconnect layer 504 in accordance with teachings of this disclosure. FIG. 5 illustrates at least a portion of an example first interconnect layer 504 of the IC device 500 that may be included in an IC package and/or an IC device assembly. In some examples, the first interconnect layer 504 and the associated dielectric structures 502 of the illustrated example can be provided or fabricated within the die(s) 102, 300 of FIGS. 1 and/or 3, the package substrate 302 of FIG. 3, the interposer 404 of FIG. 4, a redistribution layer (RDL), and/or any other structure of a semiconductor package and/or electronic device.

Many of the components of the example IC device 500 of FIG. 5 are substantially similar or identical to the components described above in connection with the IC device 200 of FIG. 2, the IC package 300 of FIG. 3, and/or the IC device assembly 400 of FIG. 4. As such, those components will not be described in detail again below. Instead, the interested reader is referred to the above corresponding descriptions for a complete written description of the structure and operation of such components.

The first interconnect layer 504 is disposed on a first surface 506 of an example first (e.g., lower) portion 508 (e.g., an underlying substrate) of the IC device 500. In some examples, the first portion 508 includes a carrier (e.g., a silicon or glass wafer or panel). In some examples, the first portion 508 includes a core (e.g., a glass core, an organic core, etc.) of a package substrate (e.g., the package substrate 302 of FIG. 3). In some examples, the first portion 508 includes one or more additional layers, such as an additional interconnect layer(s), a device layer(s), metal layers, dielectric layers, buildup layers, redistribution layers, etc.

The first interconnect layer 504 of the illustrated example includes a first insulation or dielectric material 510 and interconnect structures 512 (e.g., lithographically patterned conductive material). Specifically, the interconnect structures 512 are positioned on and extend from the first surface 506 of the first portion 508 of the IC device 500. In some examples, the interconnect structures 512 are manufactured using a semi additive processing (SAP).

The interconnect structures 512 are arranged to electrically connect components of the IC device 500 and/or components coupled to the IC device 500. In particular, the interconnect structures 512 include plurality of example traces (e.g., lines) 514 and example electrically conductive vias 516 (e.g., a self-aligned via(s), a zero-misaligned via(s), a via-on-pad(s), etc.). In some examples, one or more of the interconnect structures 512 are electrically coupled to other interconnect structures (e.g., traces, vias, etc.) in the first portion 508 of the IC device 500. Such interconnect structures in the first portion 508 have been omitted in FIG. 5 for purposes of clarity. The dielectric structures 502 of the illustrated example are integrated into the IC device 500. Specifically, the dielectric structures 502 of the illustrated example are fabricated with the IC device 500 in-situ.

The traces 514 define signal traces (e.g., signaling lines) to transfer signals or information between various components (e.g., transistors, capacitors, resistors, backend layers, etc. and/or other circuitry) and/or power traces for transferring or carrying power to the various components. The vias 516 (e.g., copper plated vias) extend through the first dielectric material 510 within the first interconnect layer 504 to electrically interconnect adjacent interconnect structures (e.g., in upper and/or lower interconnect layers). The interconnect structures 512 can include copper, gold, aluminum and/or any other electrically conductive material(s). Although a particular number of interconnect structures 512 is depicted in FIG. 5, examples of the present disclosure include IC devices having more or fewer interconnect structures than depicted.

In this example, each interconnect structure 512 of FIG. 5 includes an example seed layer 518 disposed on the first surface 506 of the first portion 508 of the IC device 500. In other words, the seed layer 518 is adjacent (e.g., in contact with) the first surface 506 of the first portion 508 of the IC device 500. In other examples, less than all the interconnect structures 512 can include the seed layer 518. Further, each interconnect structure 512 includes an electrically conductive material 520 disposed on the seed layer 518. The electrically conductive material 520 enables propagation of electrical signals through the IC device 500. For example, the electrically conductive material 520 can include copper, gold, aluminum and/or any other electrically conductive material(s). In some examples, the seed layer 518 includes or is defined by a material substantially similar to or the same as the conductive material 520. In some examples, the seed layer 518 is formed of a material that is different than the electrically conductive material 520. In some examples, the seed layer 518 is omitted and the conductive material 520 is directly adjacent (e.g., in contact with) the first surface 506 of the first portion 508 of the IC device 500.

As illustrated in FIG. 5, each trace 514 includes a first (e.g., lateral) wall 522 (e.g., surface, etc.), a second (e.g., lateral) wall 524 (e.g., surface, etc.) opposite to the first wall 522, a third (e.g., upper) wall 526 (e.g., surface, etc.) that extends between the first and second walls 522, 524 and faces away from the underlying substrate (e.g., the first portion 508), and a fourth (e.g., base) wall 528 (e.g., surface, etc.) opposite the third wall to face towards the underlying substrate (e.g., the first portion 508). In this example, the walls 522, 524, 526, 528 are defined by or include a least a portion of the seed layer 518 and/or the conductive material 520.

The vias 516 extend between two or more adjacent metal layers. The vias 516 include the conductive material 520 within an aperture (e.g., a through hole) generated within the first dielectric material 510. In particular, the vias are filled or plated with the electrically conductive material 520 along a longitudinal length of the aperture. In some examples, the conductive material 520 of one or more of the vias 516 is the same conductive material 520 as one or more of the traces 514. In some examples, the conductive material 520 of one or more of the vias 516 is a different conductive material 520 from one or more of the traces 514. The conductive material 520 within the vias 516 define example via wall(s) 530 formed of an electrically conductive material 520. In other words, the vias 516 extend through the first dielectric material 510 and electrically interconnect conductive layers of the IC device 500. Thus, the first dielectric material 510 surrounds the via wall(s) 530 of the vias 516.

In the illustrated example of FIG. 5, an example barrier layer or material 532 (e.g., a diffusion barrier, etc.) surrounds or encapsulates each trace 514 and each via 516. In particular, the barrier material 532 surrounds the first, second, and third walls 522, 524, 526 of the traces 514 and the via walls 530 of the vias 516. In other words, the barrier material 532 surrounds portions of the trace 514 defined by the first, second, and third walls 522, 524, 526, but not the fourth wall 528 (which is in contact with the first portion 508 of the IC device). The barrier material 532 prevents or reduces copper diffusion through a SiO2 or carbon doped oxide (CDO) used for the dielectric material(s) 510. As discussed in further detail below in relation to FIG. 8, in some examples, the barrier material 532 can be omitted for one or more of the interconnect structures 512. For example, the barrier material 532 can include titanium nitride, tantalum nitride, cobalt, ruthenium, and/or another barrier material.

The interconnect structures 512 are associated with outer (e.g., exterior, etc.) surfaces 534. In this example, the outer surfaces 534 correspond to the barrier material 532. The outer surfaces 534 are those surfaces not disposed on the first surface 506 of the first portion 508 and/or a second (e.g., upper) surface 536 of the first interconnect layer 504. In other examples, such as those in which the barrier material 532 is omitted, the outer surfaces 534 may correspond to one or more walls 522, 524, 526 of the traces 514 and/or the via walls 530 of the via 516. As illustrated in FIG. 5, the first dielectric material 510 surrounds the barrier material 532 on the first, second, and third walls 522, 524, 526 of the traces 514 and th via walls 530 of the vias 516.

As illustrated in FIG. 5, the interconnect structures 512 are spaced apart from one another such that an example distance or space 538 (e.g., area, etc.) is disposed between adjacent ones of the interconnect structures 512. In the illustrated example of FIG. 5, an example dielectric structure 502 is disposed within each space 538, between adjacent ones of the interconnect structures 512. In other examples, less than all of the spaces 538 include a dielectric structure 502. The dielectric structure 502 includes an example trench 540 (e.g., cavity, recess, void, gap, etc.) enclosed by the first dielectric material 510. In particular, the first dielectric material 510 is a solid-state dielectric material. For example, the first dielectric material 510 can include hafnium oxide, hafnium silicon oxide, lanthanum oxide, silicon dioxide, silicon nitride, silicon carbon nitride, and/or another solid-state, electrically insulating dielectric material(s). Put another way, the dielectric structure 502 is an enclosed cavity that is substantially devoid of solid matter

An example second dielectric material 542 is disposed within the trench 540. In particular, in some examples, air is disposed within the trench 540. In other words, the dielectric structures 502 includes airgaps defined by the first dielectric material 510 and the trenches 540 within the first dielectric material 510. In some examples, a different gas other than air is disposed within the trench 540. In some examples, the trench 540 has a pressure less than atmospheric pressure (e.g., a vacuum, under-pressured, etc.). Stated generally, the trench 540 is substantially devoid of solid matter. As used herein, substantially devoid means at least 99% devoid of solid matter.

In some examples, the trenches 540 extend to a height at least as great or greater than a height 544 of the traces 514 (e.g., a height of the first and/or second walls 522, 524). In other examples, the trenches 540 may have a height less than the height of the traces 514. In some examples, the trench 540 is elongate and has a length (into and out of the drawing from the perspective of FIG. 5) corresponding to the length of the traces 514. That is, in some examples, the trenches 540 extend along all or substantially all of the length of the traces 514. Furthermore, in some examples, where a particular trace 514 includes a bend (e.g., changes direction at a corner), an adjacent trench 540 will also include a bend to follow the direction of the trace 514. By integrating an airgap in the spaces 538 between the interconnect structures 512 (e.g., along the lengths of the traces 514), the dielectric structures 502 provide a relatively low dielectric constant of a dielectric between adjacent ones of the interconnect structures 512. This can be achieved even when the solid-state first dielectric material 510 is associated with a relatively high dielectric constant (e.g., higher than 2 or 3).

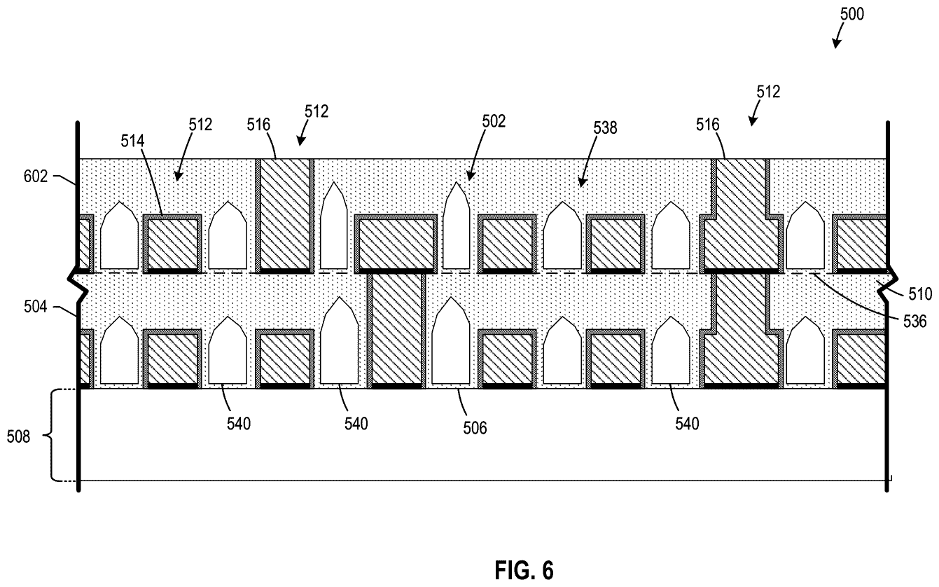

As illustrated in FIG. 5, the trench 540 is “buried” away from a processing surface (e.g., the surface of the first dielectric material 510 facing away from the underlying substrate (e.g., the first portion 508 of the IC device 500). That is, in some examples, the trenches 540 are closed off at an upper extremity (e.g., farthest away from the first portion 508) by the first dielectric material 510. Stated differently, after a chemical mechanical planarization (CMP) or a plasma-based via reveal process (e.g., removal of excess dielectric over the vias after deposition), the first dielectric material 510 of a resulting surface (e.g., the second surface 536) remains closed or continuous, leaving little to no openings or cracks exposing the enclosed trenches 540 contained therein. As discussed in further detail below in relation to FIG. 6, this makes stacking two or more layers having example dielectric structures containing trenches or airgaps as disclosed herein no more costly or complex than creating layers without such trenches or airgaps.

FIG. 6 illustrates the example IC device 500 of FIG. 5, including at least a portion of an example second interconnect layer 602. In this example, the second interconnect layer 602 is positioned directly adjacent to the first interconnect layer 504. In particular, the second interconnect layer 602 is disposed on the second surface 536 of the first interconnect layer 504. After a formation of the second surface 536, the second interconnect layer 602 can be added on the first interconnect layer 504.

The second interconnect layer 602 of the illustrated example is similar to the first interconnect layer 504. In particular, the second interconnect layer 602 includes interconnect structures 512, including example traces 514 and example vias 516, as well as example dielectric structures 502 in accordance with teachings disclosed herein. However, examples disclosed herein are not limited thereto. Rather, the first interconnect layer 504 and/or the second interconnect layer 602 may be arranged according to a wide variety of designs (in particular, the arrangement is not limited to the particular configurations of depicted in FIGS. 5 and 6).

The second interconnect layer 602 includes the example dielectric structures 502 positioned within spaces 538 between the interconnect structures 512. As illustrated in FIG. 6, the dielectric structures 502 are stackable. More particularly, the interconnect layers 504, 602 containing the dielectric structures 502 are stackable so that corresponding ones of the dielectric structures 502 may be aligned or overlap in a direction perpendicular to the second surface 536. However, as shown in the illustrated example, the aligned (e., stacked) dielectric structures 502 remain separated by the portion of the first dielectric material 510 in the first interconnect layer 504 that closed off the upper extremity of the dielectric structures 502 as discussed above. As such, multiple interconnect layers with dielectric structures 502 may be built-up because trenches 540 within any given interconnect layer are closed off before deposition of a subsequent layer. In other words, dielectric structures 502 are such that after manufacturing a given layer, a subsequent layer can be easily created over the given layer without special requirements or considerations. In particular, the subsequent layer can be processed directly onto the given layer containing the dielectric structures 502 disclosed herein without the need for additional hard-masks, barriers, curing, and/or outgassing, etc.

Although the interconnect structures 512 and the trenches 540 in the different layers 504, 602 of FIG. 6 are shown as being in vertical alignment, other arrangements are possible in other example. For example, the trenches 540 and/or interconnect structures 512 may be offset relative to one another. Further, in the illustrated example FIG. 6, the traces 514 and associated trenches 540 extend into and out of the illustrated example of FIG. 6 from the perspective shown. However, in other examples, traces 514 and/or associated trenches 540 in one layer 504, 602 can extend at angles relative to traces 514 and associated trenches 540 in another layer 504, 602. In other words, there is no limitation in the position of the interconnect structures 512 and trenches 540 in a given layer 504, 602 with respect to the interconnect structures 512 and trenches 540 in another layer 504, 602. This independence of layout in each layer 504, 602 is made possible in part by the closing off of the trenches 540 at their peak and the additional dielectric material 510 added thereafter such that each new layer 504, 602 begins on a unconstrained flat surface 536 of dielectric material 510 (except for constraints associated with locations of the vias 516 extending through the dielectric material 510).

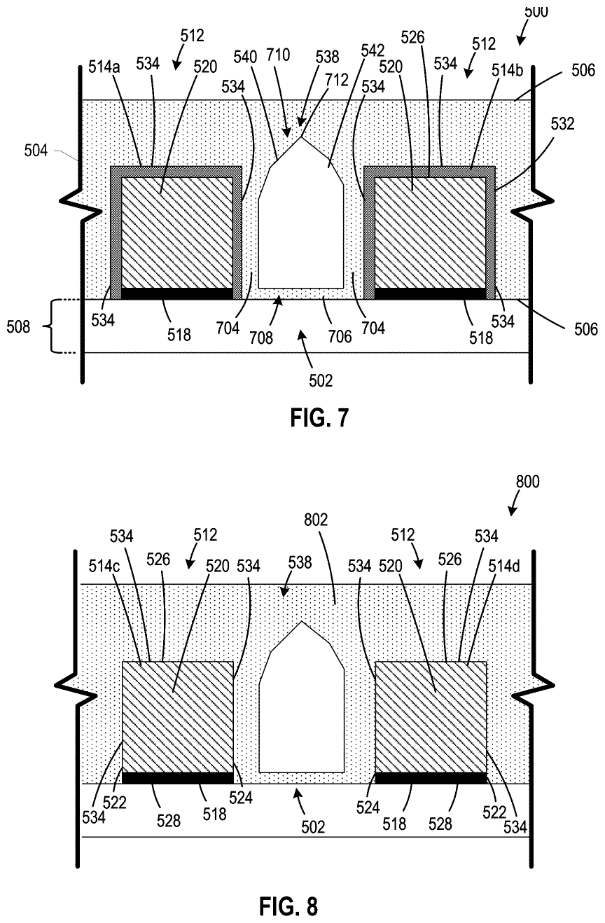

FIG. 7 is an enlarged portion of the IC device 500 of FIG. 5, including two interconnect structures 512 of the IC device 500 of FIG. 5. In particular, FIG. 7 illustrates an example first trace 514a (e.g., a first line) and an example second trace 514b (e.g., a second line). Each trace 514a, 514b includes a seed layer 518 disposed on the first surface 506 of the first portion 508 of the IC device 500. Further, a conductive material 520 is disposed on each seed layer 518. In the example of FIG. 7, the traces 514a, 514b are surrounded or enclosed by a barrier material 532. Thus, outer surfaces 534 associated with the traces 514a, 514b correspond to the barrier material 532. The first dielectric material 510 surrounds the outer surfaces 534 associated with the traces 514a, 514b (e.g., the barrier material 532 that encapsulate the traces 514a, 514b).

An example dielectric structure 502 disclosed herein is positioned in a space 538 between the first trace 514a and the second trace 514b. As discussed above, the dielectric structure 502 includes a trench 540 enclosed by the first dielectric material 510. The material properties of the first dielectric material 510 and a second dielectric material 542 (which, in some cases, is air) disposed within the trench 540 define a dielectric constant of the dielectric structure 502. In other words, a combination of the first dielectric material 510 and a second dielectric material 542 result in dielectric constant for dielectric structure 502 provided between the first and second traces 514a, 514b that is different than the dielectric constant for either of the first or second dielectric materials 510, 542 individually.

As illustrated in FIG. 7, the trench 540 is defined by example lateral walls 704 of the dielectric structure 502 that extend from an example base 706 of the dielectric structure 502. The lateral walls 704 are formed of the first dielectric material 510, and extend from respective ones of first and second walls 522, 524 of the traces 514a, 514b. In this example, the lateral walls 704 are narrower nearer the first surface 506 of the lower portion 508 of the IC device 500, and wider as they approach the third wall 526 of the trace 514a, 514b. In other words, the trench 540 is wider at a first (e.g., lower, base, etc.) portion 708 of the trench 540 (e.g., nearer the first surface 506 of the lower portion 508 of the IC device 500) and narrower near a second (e.g., upper, top, etc.) portion 710 of the trench 540 (e.g., nearer the second surface 536 of the first interconnect layer 504). Stated differently, the first portion 708 of the trench 540 is wider than the second portion 710 of the trench 540.

The base 706 of the dielectric structure 502 can have a rectangular shape and/or any other shape. In some examples, the base 706 can be larger or smaller than shown in the illustrated example of FIG. 7. In other words, a distance from the first surface 506 of the lower portion 508 of the IC device 500 to the base portion 708 of the trench 540, which is occupied by the first dielectric material 510, can be larger or smaller in other examples. In some examples, the distance from the first surface 506 of the lower portion 508 of the IC device 500 to the base portion 708 of the trench 540 is reduced (e.g., minimized, eliminated) to further reduce a dielectric constant of the dielectric structure 502. The trenches 540 illustrated in FIGS. 5-7 are substantially symmetrical. However, in other examples, one or more trenches 540 can be asymmetrical. Rather, the trenches 540 can have a wide variety of shapes and/or cross sections. In some examples, the second portion 710 of the trench 540 can bend towards the first trace 514a or the second trace 514b.

As illustrated in FIG. 7, the dielectric structure 502 includes an example closed-off point or region 712 (e.g., apex, peak, etc.) at which the lateral walls 704 meet one another. In this example, where the trench 540 has a symmetrical shape, the closed-off region 712 points in a direction directly away from the first surface 506 of the base portion 508. In examples where the trench is asymmetrical and bends towards one side, the closed-off region 712 may point off to the side at an acute angle relative to the first surface 506 of the base portion 508. In some such examples, the bend in the trench 540 and the height of the trench 540 result in the second (upper) portion 710 of the trench 540 extending over one of the traces 514 such that trace is directly between the base portion 508 and the second portion 710 of the trench 540 along a line extending normal to the first surface 506 of the base portion 508. In the illustrated example of FIG. 7, the closed-off region 712 is a sharp point. However, examples disclosed herein are not limited thereto. Rather, the second portion 710 of the trench 540 can have other shapes and/or features in other examples. For example, the second portion 710 of the trench 540 can an arched (e.g., rounded, etc.) cross-section, etc.

FIG. 8 is a cross sectional view of another example IC device 800 constructed in accordance with teachings disclosed herein. The IC device 800 of FIG. 8 is similar to the IC device 500 of FIGS. 5-7. For example, the IC device 800 includes example interconnect structures 512, including an example third trace 514c and an example fourth trace 514d. The IC device 800 includes another example dielectric structure 502 positioned in a space 538 between the third trace 514c and the fourth trace 514d.

As illustrated, each trace 514c, 514d in FIG. 8 includes a first wall 522, a second wall 524 opposite to the first wall 522, and a third wall 526 that extends between the first and second walls 522, 524, and faces away from the underlying substrate, and a fourth wall 528 opposite the third wall 526. The third and fourth traces 514c, 514d include seed layers 518 on which electrically conductive material 520 is disposed. However, the third and fourth traces 514c, 514d of FIG. 8 do not include a barrier material (e.g., barrier material 532 of FIG. 7) surrounding or encapsulating the traces 514c, 514d. Rather, the IC device 800 of FIG. 8 includes an example third dielectric material 802 that surrounds and is in direct contact with the first, second, and third walls 522, 524, 526 of the traces 514c, 514d. In this example, the third dielectric material 802 surrounding the third and fourth traces 514c, 514d is formed of a material that provides a barrier against copper diffusion, such as (but not limited to) SiCN and/or Si3N4 dielectric materials. In this example, the first, second, and third walls 522, 524, 526 of the traces 514c, 514d are outer surfaces 534 in contact with the third dielectric material 802.

FIG. 9 is a schematic illustration of another example IC device 900 (e.g., the IC device 500 of FIGS. 5-7, the IC device 800 of FIG. 8, and/or another IC device) having an example dielectric structure 502 in accordance with teachings of this disclosure. The IC device 900 includes interconnect structures 512, including example traces 514. In particular, the IC device 900 of the illustrated example includes the third and fourth traces 514c, 514d of FIG. 8. Thus, the traces 514c, 514d illustrated in FIG. 9 do not include a barrier material 532. However, examples disclosed herein are not limited hereto. Rather, the interconnect structure 512 can include additional or alternative traces 514 (e.g., the first and/or second traces 514a, 514b of FIG. 7, etc.), a via(s), and/or another type(s) of interconnect structure(s).

Each trace 514 of FIG. 9 includes a seed layer 518, a first wall 522, a second wall 524, and a third wall 526. The dielectric structure 502 is positioned in a space 538 between the interconnect structures 512. The space 538 is defined by a first distance (d₁) 902 between a first outer surface 532a of the third trace 514c and a second outer surface 532b of the fourth trace 514d. In this example, the first distance (d₁) 902 is between a third wall 526a of the third trace 514c and a first wall 522a of the fourth trace 514d.

The dielectric structure 502 is formed of a solid-state dielectric material (e.g., the first dielectric material 510, the third dielectric material 802, and/or another dielectric material) and a trench 540 positioned therein. The trench 540 includes a width defined by second distance (d₂) 904 extending from a first lateral wall 704a to a second lateral wall 704b. Further, each lateral wall 704a, 704b is associated with a third distance (d₃) 906 extending from a respective wall 522a, 524b to the trench 540. In particular, the first lateral wall 704a is associated with a third distance (d₃) 906 and the second lateral wall 704b is associated with another third distance (d₃) 906. In the illustrated example of FIG. 9, the width of the trench 540 is shown to be constant along the height of the trench 540 (e.g., the trench is rectangular) for purposes of explanation and simplicity. However, as discussed above, in some examples, the trench 540 can narrow from the base of the trench 540 towards the top of the trench 540 and/or have any other shape.

For the sake of simplicity and for illustrative purposes only, the third distances (d₃) 906 associated with respective ones of the lateral walls 704a, 704b are substantially similar. However, one or more of the third distances (d₃) 906 can differ in other examples. Further, in this example, the second distance (d₂) 904 is twice as large as each one of the third distances (d₃) 906 for the sake of simplicity and for illustrative purposes only. In other examples, the distances (d₁, d₂, d₃) 902, 904, 906 can differ.

As illustrated in FIG. 9, a first portion 908 of the dielectric structure 502 corresponding to a combination of the third distances (d₃) 906 (e.g., the third distance 906 on both sides of the trench 540) is filled with a solid-state dielectric (e.g., the first dielectric material 510, the third dielectric material 802, and/or another dielectric material). In this example, the first portion 908 (including portions of the solid-state dielectric on both sides of the trench 540) accounts for approximately one half of the first distance (d₁) 902 between a third wall 526a of the third trace 514c and a first wall 522a of the fourth trace 514d. In other words, each third distances (d₃) 906 corresponds to approximately one quarter of the first distance (d₁) 902. Stated differently, the solid-state dielectric material 510, 802 of this example occupies approximately half of the dielectric structure 502.

As illustrated in FIG. 9, a second portion 910 of the dielectric structure 502 corresponding to the second distance (d₂) 904 is filled with a second dielectric material 542 (e.g., air, another gas, etc.). In this example, the second portion 910 accounts for approximately one half of the first distance (d₁) 902 between a third wall 526a of the third trace 514c and a first wall 522a of the fourth trace 514d. In other words, the trench 540 of this example occupies approximately half of the dielectric structure 502. It is understood that the first portion 908 and/or the second portion 910 can be larger or smaller and/or of another geometry in additional or alternative examples.

Based on the foregoing distances associated with the illustrated example of FIG. 9, an example evaluation of example dielectric constants that can be achieved by the example dielectric structures 502 disclosed herein is provided in Table 1. In other words, Table 1 provides approximate dielectric constants for the dielectric structure 502 of the IC device 900 in FIG. 9, for different solid-state dielectric materials 510, 802, including silicon dioxide (SiO₂), Silicon carbon nitride (SiCN), and silicon nitride (Si₃N₄). Stated differently, Table 1 includes example dielectric constants that can be reached in the space 538 between the interconnect structures 512. In Table 1, the second dielectric material (e.g., the material in the trench 540) is assumed to be air (with a dielectric constant (k) of approximately 1).

TABLE 1

| | | Inter-Interconnect Dielectric |
|---|---|---|
| First | | Constant (e.g., dielectric |
| Dielectric | Dielectric | constant between |
| Material | Constant (K) | interconnect structures) |
| SiO₂ | ~3.9 | ~1.6 |
| SiCN | ~4.5-605 | ~1.64-.173 |
| Si₃N₄ | ~7.5 | ~1.77 |

As discussed above, the dielectric structure 502 disclosed herein is associated with relatively low dielectric constant. This can be achieved even when the solid-state dielectric material 510, 802 is associated with a relatively high dielectric constant (e.g., a higher k than SiO2). As illustrated in Table 1, the inter-interconnect dielectric constants are each below two, allowing for improved signal isolation from interconnect structure 512 to interconnect structure 512. These relative inter-interconnect dielectric constants also enable relatively low time-delay constants for such interconnect structures 512. This increases (e.g., maximizes) the bandwidth per line and the bandwidth density that can be achieved per unit length for high-density die-to-die interconnects and for classical package-based HSIO (high-speed IO) interconnects (e.g., relative to redistribution layer HSIO interconnects or interconnects on package substrates). It must be noted that the values in Table 1 do not take stray fields into account which may slightly increase real-world inter-interconnect dielectric constants. Further, the values provided in Table 1 assume the particular geometric shape for the trench 540 (e.g., rectangular) and the associated dimensions or distances 902, 904, 906 shown in FIG. 9 as detailed above. In other examples, where the trench 540 has a different shape (e.g., as shown and discussed above in connection with FIGS. 5-8), the resulting dielectric constant for the inter-interconnect region (e.g., the dielectric structure) may be different.

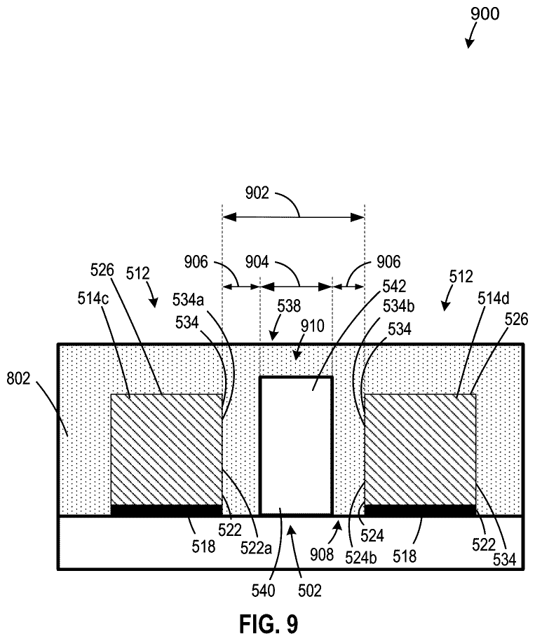

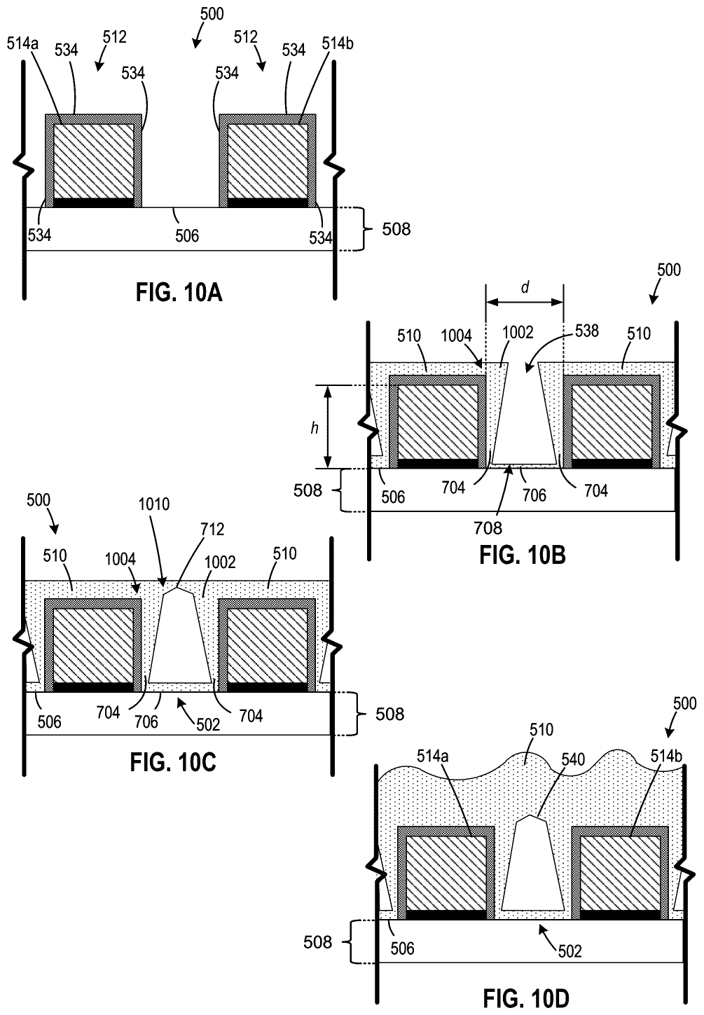

FIGS. 10A-10D illustrate various stages of manufacture of the example dielectric structures 502 disclosed herein. In particular, FIGS. 10A-10D illustrate an example method to manufacture an example IC device (e.g., IC device 200 of FIG. 2, IC device 500 of FIGS. 5-7, IC device 800 of FIG. 8, IC device 900 of FIG. 9, and/or any other structure having a dielectric structure 502 disclosed herein). For example, FIGS. 10A-10D are cross-sectional illustrations of the example IC device 500 of FIGS. 5-7 at various manufacturing stages. For purposes of explanation, FIGS. 10A-10D have been simplified to produce an interconnect layer 504 with only one dielectric structure 502. However, any suitable number of dielectric structures 502 may be implemented.

Turning in detail to the drawings, FIG. 10A illustrates the IC device 500 prior to deposition of a solid-state first dielectric material 510, 802. In the illustrated example of FIG. 10A, the IC device 500 includes interconnect structures 512 provided on the first surface 506 of the lower portion 508 of the IC device 500. In particular, the IC device 500 includes a first trace 514a and a second trace 514b. The interconnect structures 512 can be patterned on the first surface 506 of the lower portion 508 of the IC device 500 via lithography and/or deposited and patterned on the surface 506 of the lower portion 508 of the IC device 500 via deposition. Further, the barrier material 532 can be fabricated or deposited using suitable deposition techniques for semiconductor devices. As illustrated in FIG. 10A, the barrier material 532 is deposited on all outer surfaces 534 associated with the traces 514a, 514b. As discussed above, in some examples, the barrier material 532 is omitted.

FIG. 10B illustrates the IC device 500 after deposition of a portion of the first dielectric material 510. In particular, FIG. 10B illustrates the IC device 500 after deposition of the base 706 and the lateral walls 704 of the dielectric structure 502. The lateral walls 704 are formed of the first dielectric material 510, and extend from respective ones of first and second walls 522, 524 of the traces 514a, 514b. The base 706 is formed of the first dielectric material 510, and extends from the first surface 506 of the lower portion 508 of the IC device 500. In some examples, the first dielectric material 510 is deposited for both the base 706 and the lateral walls 704 of the dielectric structure 502 at the same time using a chemical vapor deposition (CVD) process. However, any suitable process to deposit the first dielectric material 510 can be used.

In some examples, as discussed above, the lateral walls 704 are narrower nearer the first surface 506 of the lower portion 508 of the IC device 500, and wider as they approach the third wall 526 of the trace 514a, 514b. The slanted (narrowing) shape of the lateral walls 704 of the dielectric structure 502 is achieved by manipulation of adjustable parameters of the deposition process, including (but not limited to) deposition rate, gas flow, an amount of material, temperature, pressure, power, etc. For example, adjusting a gas flow rate and/or one or more other parameters noted above during the deposition process enables adjustment of a shape of the lateral walls 704 and, consequently, a shape of the trench 540. To achieve the cross-section illustrated in FIG. 10B, a higher rate of growth is used near the third walls 526 of the traces 514a, 514b relative to a lower rate of growth used near the first surface 506 of the lower portion 508 of the IC device 500. This results in the developing of overhangs 1002 at the upper corners 1004 of the interconnect structures 512 where the dielectric material 510 grows or is deposited more quickly than the dielectric material 510 deposited for the base 706.

FIG. 10C illustrates the IC device 500 after formation of the trench 540. In particular, the dielectric structure 502 is formed by tailoring the deposition process such that during growth of the dielectric material 510, an overhang 1002 forming at a corner 1004 of the interconnect structures 512 grows faster and pinches off a growth front where the base 706 of the dielectric structure is being deposited, leaving the trench 540. In other words, the trench 540 is formed by adjusting the deposition process such that the first dielectric material 510 closes faster at near the second portion 710 of the trench 540, until the lateral walls 704 meet one another to form the closed-off region 712. Before the overhangs 1002 meet to pinch off at the closed-off region 712 during the deposition process, some of the dielectric material 510 can enter the trench 540 to be deposited on the base 706. However, due to the overhang 1002, the deposition may not be evenly distributed across the base 706 such that the base 706 may have a cross-sectional shape characterized by a mound near a middle (e.g., rather than flat as shown in the FIG. 10C).

In some examples, experiments can be conducted to determine deposition parameters that will achieve a desired trench 540. For example, experiments may be conducted using a dedicated high rate deposition tool (e.g., dielectric gap-fill tool). Optimization of deposition parameters will yield very similar values for the dielectric number k for such shapes.

In some examples, an aspect ratio of the space 538 between interconnect structures 512 can be determinative of whether a trench 540 will form. For example, an aspect ratio of the space 538 between the first trace 514a and the second trace 514b corresponds to a height (h) of the traces 514a, 514b relative to a distance (d) between the traces 514a, 514b. If this aspect ratio is relatively low (e.g., below 0.5), the distance (d) between the traces 514a, 514b is more than twice the height (h) of the traces 514a, 514b. In some such examples, the trench 540 may be difficult to form as the overhang 1002 formed at corners 1004 of the traces 514a, 514b may not grow fast enough to pinch off at the top when the opposing overhangs 1002 meet before the space 538 between the interconnect structures 512 (e.g., below the overhangs 1002) fill up with the dielectric material 510 associated with the base 706. Accordingly, in some examples, the aspect ratio of the space 538 is at least 0.5 (e.g., at least 0.75, at least 1, at least 1.25, etc.).

FIG. 10D illustrates the IC device 500 after deposition of the first dielectric material 510 to cover the trench 540 and the traces 514a, 514b. In particular, excess first dielectric material 510 may be deposited to cover each trench 540 in the layer and/or to a desired via length. Thus, the trenches 540 of the dielectric structure 502 and the traces 514a, 514b are encapsulated by the first dielectric material 510.

While an example manner of fabricating the example dielectric structures 502 has been illustrated in 10A-10D, one or more of the steps and/or processes illustrated in FIGS. 10A-10D may be combined, divided, re-arranged, omitted, eliminated and/or implemented in any other way. Further still, the example of FIGS. 10A-10D may include processes and/or steps in addition to, or instead of, those illustrated in FIGS. 10A-10D and/or may include more than one of any or all of the illustrated processes and/or steps.

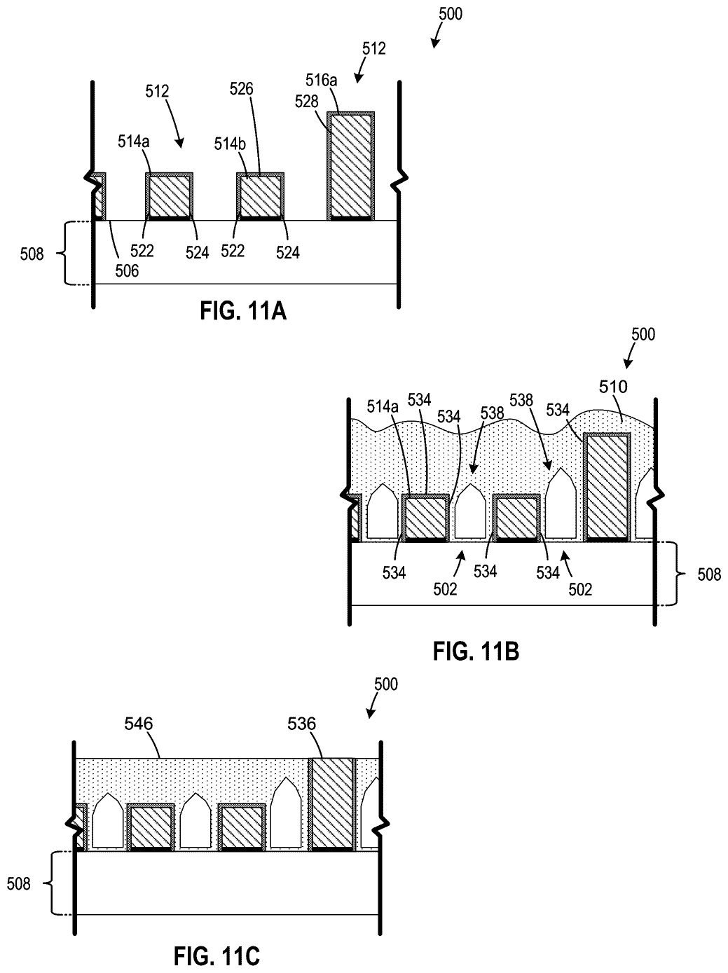

FIGS. 11A-11C illustrate various stages of manufacture of the example IC device 500 of FIGS. 5-7. The manufacturing of the interconnect structures 512 is not elaborated as different flows can be utilized. Rather, different methods and processes can be used to achieve similar results.

FIG. 11A illustrates an IC device 500 after interconnect structures 512 have been deposited or otherwise manufactured on the first surface 506 of the lower portion 508 of the IC device 500. In particular, an example first trace 514a, an example second trace 514b, and an example first via 516a have been positioned on the first surface 506 of an underlying substrate. In this example, the interconnect structures 512 include the barrier material 532 surrounding or encapsulating the first, second, and third walls 522, 524, 526 of the traces 514a, 514b and the via wall 528 of the first via 516a. In this example, the first via 516a is a self-aligned (e.g., zero-misaligned) via. However, the first via 516a can be another type of via in other examples.

FIG. 11B illustrates the IC device 500 after manufacture or formation of the example dielectric structures 502 disclosed herein. In particular, FIG. 11B illustrates the IC device 500 after deposition of the first dielectric material 510 such that trenches 540 form in the first dielectric material 510 deposited in the spaces 538 between adjacent ones of the interconnect structures 512. For example, the deposition process can be similar to that described above in relation to FIGS. 10A-10D.

FIG. 11C illustrates the IC device 500 after removal of unwanted or excess portions of the dielectric material 510, 802. In particular, a CMP/via reveal process may be applied to complete the layer. In some examples, the excess portions of the dielectric material 510, 802 is removed using a suitable technique, such as a dry etching technique.

While an example manner of fabricating the example IC device 500 has been illustrated in 11A-11C, one or more of the steps and/or processes illustrated in FIGS. 11A-11C may be combined, divided, re-arranged, omitted, eliminated and/or implemented in any other way. Further still, the example methods of FIGS. 11A-11C may include processes and/or steps in addition to, or instead of, those illustrated in FIGS. 11A-11C and/or may include more than one of any or all of the illustrated processes and/or steps.

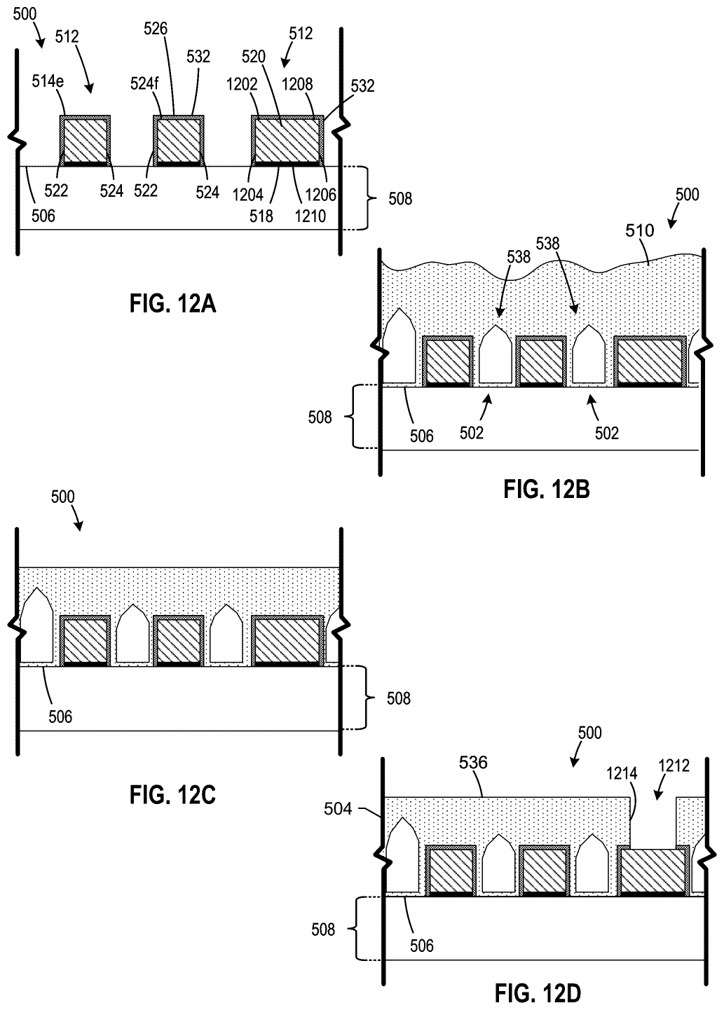

FIGS. 12A-12D illustrate various stages of manufacture of another portion the example IC device 500 of FIGS. 5-7. The manufacturing of the interconnect structures 512 is not elaborated as different flows can be utilized. Rather, different methods and processes can be used to achieve similar results.

FIG. 12A illustrates an IC device 500 after interconnect structures 512 have been deposited or otherwise manufactured on the first surface 506 of the lower portion 508 of the IC device 500. In particular, an example fifth trace 514e, an example sixth trace 514f, and an example via pad 1202 have been positioned on the first surface 506 of an underlying substrate. In this example, the fifth and sixth traces 514e, 514f are substantially similar to the first and second traces 514a, 514b of FIGS. 11A-11D. Similarly, the via pad 1202 is substantially similar to the traces 514 disclosed herein. In particular, the via pad 1202 includes a seed layer 518 on which a conductive material 520 is disposed. Further, the via pad 1202 includes a first (e.g., lateral) wall 1204 (e.g., surface, etc.), a second (e.g., lateral) wall 1206 (e.g., surface, etc.) opposite to the first wall 1204, a third (e.g., upper) wall 1208 (e.g., surface, etc.) that extends between the first and second walls 1204, 1206 and faces away from the underlying substrate (e.g., the first portion 508), and a fourth (e.g., base) wall 1210 (e.g., surface, etc.) opposite the third wall to face towards the underlying substrate (e.g., the first portion 508). In this example, the walls 1204, 1206, 1208 of the via pad 1202 are defined by or include a least a portion of the seed layer 518 and/or the conductive material 520.

In this example, the interconnect structures 512 include the barrier material 532 surrounding or encapsulating the first, second, and third walls 522, 524, 256 of the traces 514e, 514f and the first, second, and third walls 1204, 1206, 1208 of the via pad 1202. In other examples, the barrier material 532 may be omitted.

FIG. 12B illustrates the IC device 500 after manufacture or formation of the example dielectric structures 502 disclosed herein. In particular, FIG. 12B illustrates the IC device 500 after deposition of the first dielectric material 510 such that trenches 540 form in the first dielectric material 510 deposited in the spaces 538 between adjacent ones of the interconnect structures 512. For example, the deposition process can be similar to that described above in relation to FIGS. 10A-10D.

FIG. 12C illustrates the IC device 500 after removal of unwanted or excess portions of the dielectric material 510, 802. In some examples, the excess portions of the dielectric material 510, 802 is removed using a suitable technique, such as a dry etching technique.

FIG. 12D illustrates the IC device 500 after a via-reveal process. In particular, a via opening 1212 is created or recessed into the second surface 536 of the first interconnect layer 504. For example, the via pad opening 212 can be manufactured through a reactive-ion etching (REI) process or another suitable removal process that creates the via opening 1212. After the via opening 1212 is created or recessed into the second surface 536 of the first interconnect layer 504, the via opening 1212 can be filled or electroplated using as a metal deposition process (e.g., physical vapor deposition, plating, a combination thereof, etc.) to form a metal via. In other words, a conductive material can be added (e.g., filled, electroplated, etc.) to the via opening 1212 to generate an example via-on-pad. In some examples, an example wall 1214 of the via pad opening 1212 is lined with a barrier material 532 (e.g., prior to deposition of the conductive material). In some examples, the via-on-pad is created during manufacture of a subsequent interconnect adjacent or above the first interconnect layer 504.

While an example manner of fabricating the example IC device 500 has been illustrated in 12A-12D, one or more of the steps and/or processes illustrated in FIGS. 12A-12D may be combined, divided, re-arranged, omitted, eliminated and/or implemented in any other way. Further still, the example methods of FIGS. 12A-12D may include processes and/or steps in addition to, or instead of, those illustrated in FIGS. 12A-12D and/or may include more than one of any or all of the illustrated processes and/or steps.

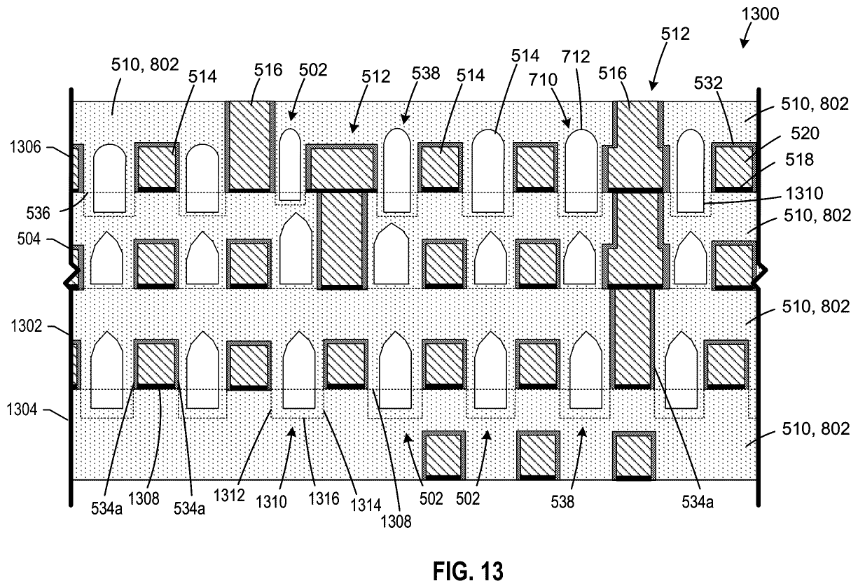

FIG. 13 is a cross-sectional side view of another example IC device 1300 including example dielectric structures 502 provided within interconnect layers that may be included in an IC package and/or an IC device assembly in accordance with teachings of this disclosure. In some examples, the interconnect layers and the associated dielectric structures 502 of the illustrated example can be provided or fabricated within the die(s) 102, 300 of FIGS. 1 and/or 3, the package substrate 302 of FIG. 3, the interposer 404 of FIG. 4, a redistribution layer (RDL), and/or any other structure of a semiconductor package and/or electronic device. Many of the components of the example IC device 1300 of FIG. 13 are substantially similar or identical to the components described above in connection with the IC device 200 of FIG. 2, the IC package 300 of FIG. 3, the IC device 500 of FIGS. 5-7 and 10-13D, the IC device 800 of FIG. 8, the IC device 900 of FIG. 9, and/or the IC device assembly 400 of FIG. 4. As such, those components will not be described in detail again below. Instead, the interested reader is referred to the above corresponding descriptions for a complete written description of the structure and operation of such components.

The IC device 1300 of FIG. 13 is similar to the IC device 500 of FIGS. 5-7 and 10A-12D. For example, the IC device 1300 includes example interconnect structures 512, including example traces 514 and example vias 516, and example dielectric structures 502 positioned in spaces 538 between adjacent ones of the interconnect structures 512. Each interconnect structure 512 includes a seed layer 518 and a conductive material 520 deposited on the seed layer 518. In this example, a barrier material 532 surrounds the interconnect structures 512. However, the barrier material 532 may be omitted in other examples.

The IC device 1300 of FIG. 13 includes an example third interconnect layer 1302 positioned on an example fourth interconnect layer 1304. Further, the IC device 1300 of FIG. 13 includes the first interconnect layer 504, which is positioned on the third interconnect layer 1302. Thus, in this example, the third interconnect layer 1302 corresponds to the first (lower) portion 508 shown in FIG. 5. However, as discussed above, in other examples, the first portion 508 can be any other type of substrate. In the illustrated example of FIG. 13, an example fifth interconnect layer 1306 is positioned on the first interconnect layer 504. Each interconnect layer 504, 1302-1306 includes a dielectric material 510, 802 surrounding the interconnect structures 512 and/or the barrier material 532. In some examples, the one or more interconnect layers 504, 1302-1306 include the same dielectric material 510, 802. In some examples, the one or more interconnect layers 504, 1302-1306 include different dielectric materials 510, 802.

As illustrated in FIG. 13, the third interconnect layer 1302 is positioned on a third surface 1308 of the fourth interconnect layer 1304, and the fifth interconnect layer 1306 is positioned on the second surface 536 of the first interconnect layer 504. In this example, the dielectric structures 502 in the third and fifth interconnect layers 1302, 1306 extend into the dielectric material 510, 802 of a respective, lower (e.g., underlying) adjacent interconnect layer (e.g., the fourth interconnect layer 1304 and the first interconnect layer 504, respectively).

In particular, the IC device 1300 includes an example recess 1310 in spaces 538 between adjacent ones of the interconnect structures 512 in the third and fifth interconnect layers 1302, 1306. In this example, the recesses 1310 in the third interconnect layer 1302 extend from the third surface 1308 of the fourth interconnect layer 1304 into at least a portion of the fourth interconnect layer 1304. The recesses 1310 in the fifth interconnect layer 1306 extend from the second surface 536 of the first interconnect layer 504 into at least a portion of the first interconnect layer 504. Further, the recesses 1310 in the illustrated example of FIG. 13 extend between lateral ones of the outer surfaces 534a associated with adjacent ones of the interconnect structures 512. In the illustrated example, the width of ones of the recesses 1310 corresponds to the distance between adjacent ones of the interconnect structures 512. In other examples, the width of ones of the recesses 1310 is less than the distance between adjacent ones of the interconnect structures 512. In some examples, the recesses 1310 are rectangular in shape. In some examples, one or more of the recesses 1310 include another shape.

As illustrated in FIG. 13, each recess 1310 includes a first (e.g., lateral) wall 1312 (e.g., surface, etc.), a second (e.g., lateral) wall 1314 (e.g., surface, etc.) opposite to the first wall 1312, and a third (e.g., base) wall 1316 (e.g., surface, etc.) that extends between the first and second walls 1312, 1314 and extends into the underlying interconnect layer 1304, 504. In this example, the walls 1312, 1314, 1316 are defined by or include a dielectric material 510, 802.

In this example, ones of the dielectric structures 502 in the third and fifth interconnect layers 1302, 1306 extend into respective ones of the recesses 1310. In other words, the ones of the dielectric structures 502 in the third and fifth interconnect layers 1302, 1306 extend into the dielectric material 510, 802 below to extend the trench 540 (e.g., airgap). Thus, in some examples, the trenches 540 extend both below and above adjacent interconnect structures 512 (at least the traces 514). In other words, in some examples, the trenches 540 are closer to an underlying surface of an underlying substrate than the adjacent interconnect structures 512 are to the surface of the underlying substrate. Further, in some examples, the trenches 540 extend farther away from the underlying surface of the underlying substrate than the adjacent interconnect structures 512 extend away from the surface of the underlying substrate. Providing trenches 540 that extend beyond (e.g., lower than) base surfaces of the adjacent the interconnect structures further lowers a dielectric constant associated with these dielectric structures 502. In some examples, a cost associated with extending the dielectric structures 502 is marginal or limited.

As illustrated in FIG. 13, in some examples, one or more trenches 540 includes a second portion 710 of the trench 540 that is arched. In other words, the closed-off region 712 of the trench 540 can be associated with a dome-like shape in some examples. Stated differently, the closed-off region 712 at near the second portion 710 of the trench 540 can have an arched profile that extends along an elongate length of the trench 540.

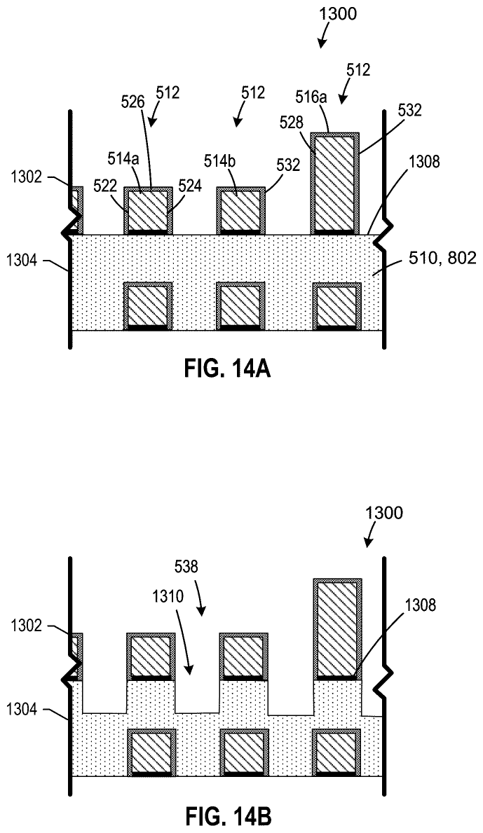

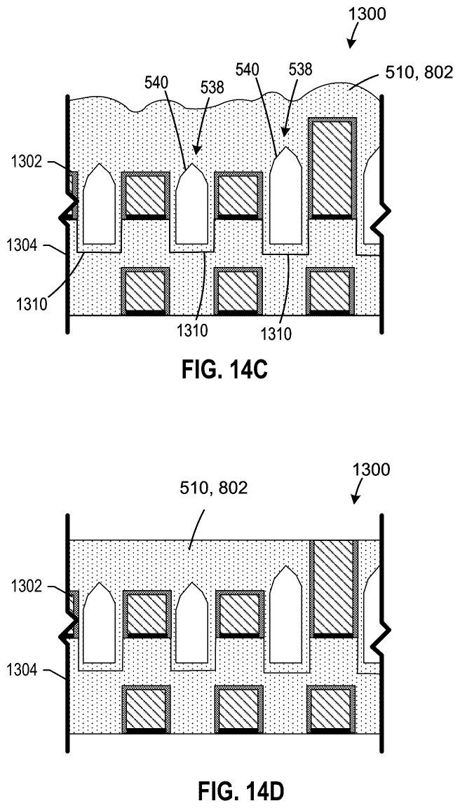

FIGS. 14A-14D illustrate various stages of manufacture of the example IC device 1300 of FIG. 13. The manufacturing of the interconnect structures 512 is not elaborated as different flows can be utilized. Rather, different methods and processes can be used to achieve similar results.

FIG. 14A illustrates an IC device 1300 after interconnect structures 512 have been deposited or otherwise manufactured on the third surface 1308 of the fourth interconnect layer 1304 of the IC device 1300. In particular, an example first trace 514a, an example second trace 514b, and an example first via 516a have been positioned on the third surface 1308 of an underlying substrate. As illustrated in FIG. 14A, the fourth interconnect layer 1304 includes traces 514 and a dielectric material 510, 802 surrounding the traces 514. In this example, the interconnect structures 512 include the barrier material 532 surrounding or encapsulating the first, second, and third walls 522, 524, 256 of the traces 514a, 514b and the via wall 528 of the first via 516a.

FIG. 14B illustrates the IC device 1300 after fabrication of the recesses 1310 into the dielectric material 510, 802 of the fourth interconnect layer 1304. The recesses 1310 can be formed in the dielectric material 510 using any suitable removal technique, such as a dry etching technique, etc. In some examples, the interconnect structures 512 serve as a mask defining the location where the dielectric material 510 is removed (e.g., at locations between the interconnect structures 512).

FIG. 14C illustrates the IC device 1300 after manufacture or formation of the example dielectric structures 502 disclosed herein. In particular, FIG. 14C illustrates the IC device 1300 after deposition of the first dielectric material 510 such that trenches 540 form in the first dielectric material 510 deposited in the spaces 538 between adjacent ones of the interconnect structures 512. For example, the deposition process can be similar to that described above in relation to FIGS. 10A-10C. Providing the recesses 1310 into an underlying layer, as shown in the illustrated example, effectively increase the aspect ratio of the spaces 538 between the interconnect structures 512 used during the formation of the trenches 540. Such higher aspect ratios can facilitate the opposing walls of the dielectric structure 502 to join together due to their overhang to define the trench 540 as discussed above in relation to FIGS. 10A-10C.

FIG. 14D illustrates the IC device 1300 after removal of unwanted or excess portions of the dielectric material 510. In particular, a CMP/via reveal process may be applied to complete the layer. In some examples, the excess portions of the dielectric material 510 is removed using a suitable technique, such as a dry etching technique.

While an example manner of fabricating the example IC device 1300 has been illustrated in 14A-14D, one or more of the steps and/or processes illustrated in FIGS. 14A-14D may be combined, divided, re-arranged, omitted, eliminated and/or implemented in any other way. Further still, the example methods of FIGS. 14A-14D may include processes and/or steps in addition to, or instead of, those illustrated in FIGS. 14A-14D and/or may include more than one of any or all of the illustrated processes and/or steps.

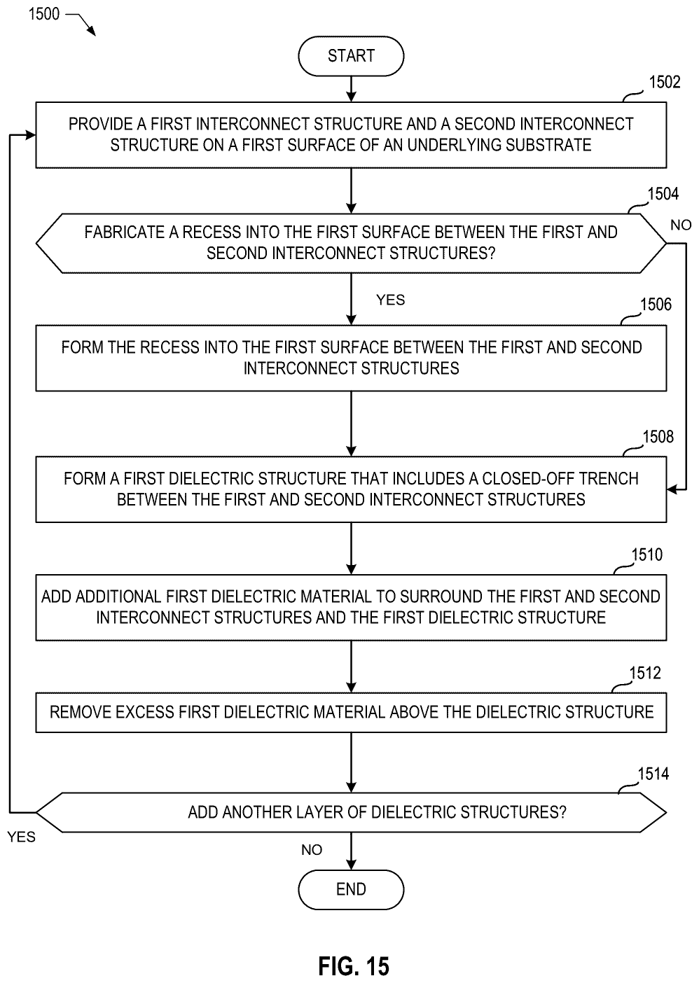

FIG. 15 is a flowchart representative of an example method 1500 of fabricating an example IC device including dielectric structures disclosed herein, such as the IC device 500 of FIGS. 5-7 and 10-12D, as represented by the example stages of manufacture shown in FIGS. 10A-10D, 11A-11C, and 12A-12D, the IC device 800 of FIG. 8, the IC device 900 of FIG. 9, the IC device 1300 of FIG. 13, as represented by the example stages of manufacture shown in FIGS. 14A-14D, and/or another IC device. For purposes of explanation, the example process of FIG. 15 will be described primarily with reference to the IC device 500 of FIGS. 5-7. However, the following discussion applies similar to any other IC device disclosed herein. The process begins with a first surface 506 of a first portion 508 of the IC device 500 (e.g., an underlying substrate). As discussed above, the first portion 508 of the IC device 500 may correspond to any suitable substrate. Therefore, any suitable number and/or types of fabrication processes may have already been completed to provide the first portion 508 prior to commencement of the example process of FIG. 15.

At block 1502, the method includes providing a first interconnect structure 512 and a second interconnect structure 512 on the first surface of the underlying structure. For example, the interconnect structures 512 can include one or more traces 514 and/or one or more vias 516. A space 538 is provided between the first and second interconnect structures 512. In some examples, more than two interconnect structures 512 are added to the underlying structure. The interconnect structures 512 can be patterned on the first surface 506 of the lower portion 508 of the IC device 500, 800, 900, 1300 via lithography and/or deposited and patterned on the surface 506 of the lower portion 508 of the IC device 500, 800, 900, 1300 via deposition. In some examples, a barrier material 532 can encapsulate or surround the interconnect structures 512.

At block 1504, the method includes determining whether to fabricate a recess 1310 into the first surface 506 between the first and second interconnect structures 512. When the answer to block 1504 is YES, the method 1500 goes to block 1506. At block 1506, the method includes forming the recess into the first surface between the first and second interconnect structures. When the answer to block 1504 is NO, the method 1500 advances to block 1508.

At block 1508, the method includes forming a first dielectric structure 502 that includes a closed-off trench 540 between the first and second interconnect structures 512. For example, the method includes depositing a first dielectric material 510, 802 to form a base 706 and lateral walls 704 of the dielectric structure 502. In some examples, the first dielectric material 510, 802 is deposited using a chemical vapor deposition (CVD) process. However, any suitable process to deposit the first dielectric material 510, 802 can be used. Further, the method includes adjusting the deposition process such that the first dielectric material 510, 802 grows (e.g., is deposited) faster near the top surface of the interconnect structures (e.g., at locations farthest from the surface of the underlying structure) so that the lateral walls 704 defines overhangs that eventually meet one another to form the closed-off region 712.

At block 1510, the method includes depositing additional first dielectric material to surround the first and second interconnect structures and the first dielectric structure. For example, the method can include deposition of the first dielectric material 510, 802 to cover the trench 540 and the interconnect structures 512. In particular, excess first dielectric material 510, 802 may be deposited to cover each trench 540 in the layer and/or to a desired via length. Thus, the trenches 540 of the dielectric structure 502 and the interconnect structures 512 are encapsulated by the first dielectric material 510, 802. In some examples, the deposition process to add the additional first dielectric is a continuation of the deposition process at block 1506 to form the first dielectric structure. That is, in some examples, blocks 1506 and 1508 correspond to a single deposition process. In other examples, blocks 1506 and 1508 are implemented in separate stages.

At block 1512, the method includes removing excess first dielectric material above the dielectric structure. In particular, the method includes removal of unwanted or excess portions of the dielectric material 510, 802. For example, a planarization and/or a via reveal process may be applied.

At block 1514, the method includes determining whether to add another layer of dielectric structures. When the answer to block 1514 is YES, example method of FIG. 15 iterates through blocks 1502-1512. In particular, the example method of FIG. 15 iterates through blocks 1502-1512 until the answer to block 1514 is NO.

While an example method of manufacturing the example dielectric structures 502 disclosed herein, one or more of the blocks in FIG. 15 may be combined, divided, re-arranged, omitted, eliminated, and/or implemented in any other way.

FIG. 16 is a block diagram of an example electrical device 1600 that may include one or more of the example dielectric structures disclosed herein. For example, any suitable ones of the components of the electrical device 1600 may include one or more of the device assemblies 400, IC packages 300, 420, IC devices 200, 300, 500, 800, 900, 1300 or dies 102, 306, disclosed herein. A number of components are illustrated in FIG. 16 as included in the electrical device 1600, but any one or more of these components may be omitted or duplicated, as suitable for the application. In some examples, some or all of the components included in the electrical device 1600 may be attached to one or more motherboards. In some examples, some or all of these components are fabricated onto a single system-on-a-chip (SoC) die.

Additionally, in various examples, the electrical device 1600 may not include one or more of the components illustrated in FIG. 16, but the electrical device 1600 may include interface circuitry for coupling to the one or more components. For example, the electrical device 1600 may not include a display 1606, but may include display interface circuitry (e.g., a connector and driver circuitry) to which a display 1606 may be coupled. In another set of examples, the electrical device 1600 may not include an audio input device 1624 (e.g., microphone) or an audio output device 1608 (e.g., a speaker, a headset, earbuds, etc.), but may include audio input or output device interface circuitry (e.g., connectors and supporting circuitry) to which an audio input device 1624 or audio output device 1608 may be coupled.

The electrical device 1600 may include programmable circuitry 1602 (e.g., one or more processing devices). The programmable circuitry 1602 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1600 may include a memory 1604, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1604 may include memory that shares a die with the programmable circuitry 1602. This memory may be used as cache memory and may include embedded dynamic random access memory (eDRAM) or spin transfer torque magnetic random access memory (STT-MRAM).

In some examples, the electrical device 1600 may include a communication chip 1612 (e.g., one or more communication chips). For example, the communication chip 1612 may be configured for managing wireless communications for the transfer of data to and from the electrical device 1600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1612 may operate in accordance with other wireless protocols in other examples. The electrical device 1600 may include an antenna 1622 to facilitate wireless communications and/or to receive other wireless communications (such as AM or FM radio transmissions).

In some examples, the communication chip 1612 may manage wired communications, such as electrical, optical, or any other suitable communication protocols (e.g., the Ethernet). As noted above, the communication chip 1612 may include multiple communication chips. For instance, a first communication chip 1612 may be dedicated to shorter-range wireless communications such as Wi-Fi or Bluetooth, and a second communication chip 1612 may be dedicated to longer-range wireless communications such as global positioning system (GPS), EDGE, GPRS, CDMA, WiMAX, LTE, EV-DO, or others. In some examples, a first communication chip 1612 may be dedicated to wireless communications, and a second communication chip 1612 may be dedicated to wired communications.

The electrical device 1600 may include battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include a display 1606 (or corresponding interface circuitry, as discussed above). The display 1606 may include any visual indicators, such as a heads-up display, a computer monitor, a projector, a touchscreen display, a liquid crystal display (LCD), a light-emitting diode display, or a flat panel display.

The electrical device 1600 may include an audio output device 1608 (or corresponding interface circuitry, as discussed above). The audio output device 1608 may include any device that generates an audible indicator, such as speakers, headsets, or earbuds.

The electrical device 1600 may include an audio input device 1624 (or corresponding interface circuitry, as discussed above). The audio input device 1624 may include any device that generates a signal representative of a sound, such as microphones, microphone arrays, or digital instruments (e.g., instruments having a musical instrument digital interface (MIDI) output).

The electrical device 1600 may include GPS circuitry 1618. The GPS circuitry 1618 may be in communication with a satellite-based system and may receive a location of the electrical device 1600, as known in the art.

The electrical device 1600 may include any other output device 1610 (or corresponding interface circuitry, as discussed above). Examples of the other output device 1610 may include an audio codec, a video codec, a printer, a wired or wireless transmitter for providing information to other devices, or an additional storage device.

The electrical device 1600 may include any other input device 1620 (or corresponding interface circuitry, as discussed above). Examples of the other input device 1620 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1600 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1600 may be any other electronic device that processes data.

The foregoing examples of the dielectric structures 502 teach or suggest different features. Although each example dielectric structures 502 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

From the foregoing, it will be appreciated that example systems, apparatus, articles of manufacture, and methods have been disclosed that improve interconnect structures in integrated circuit packages. Examples disclosed herein have lower dielectric constants of dielectrics between interconnect structures relative to known dielectrics due to an airgap within the dielectric material.

Example methods, apparatus, systems, and articles of manufacture to provide improved interconnect structures in integrated circuit packages for semiconductor packages are disclosed herein. Further examples and combinations thereof include the following:

Example 1 includes an integrated circuit (IC) package comprising a first interconnect structure positioned on a first surface of an underlying substrate, a second interconnect structure positioned on the first surface of the underlying substrate, the second interconnect structure adjacent to the first interconnect structure, and a first dielectric material between the first and second interconnect structures, the first dielectric material including an enclosed trench within a space between the first and second interconnect structures.

Example 2 includes the IC package of example 1, wherein the enclosed trench includes a second dielectric material that is different than the first dielectric material.

Example 3 includes the IC package of example 1, wherein at least one of the first interconnect structure or the second interconnect structure is a trace.

Example 4 includes the IC package of example 1, wherein at least one of the first interconnect structure or the second interconnect structure is a via that extends through the first dielectric material.

Example 5 includes the IC package of example 1, wherein the first interconnect structure has a width and a height, the enclosed trench to extend away from the first surface of the underlying substrate beyond the height of the first interconnect structure.

Example 6 includes the IC package of example 1, wherein the enclosed trench includes a first portion and a second portion, the second portion having an arched cross-section.

Example 7 includes the IC package of example 1, wherein the first and second interconnect structures are in a first interconnect layer of the IC package, the first interconnect layer including a second surface facing away from the first surface of the underlying substrate.

Example 8 includes the IC package of example 7, wherein the space is a first space, the enclosed trench is a first enclosed trench, the IC package further including a second interconnect layer, the second interconnect layer including a third interconnect structure positioned on the second surface of the first interconnect layer, a fourth interconnect structure positioned on the second surface of the first interconnect layer, the fourth interconnect structure adjacent to the third interconnect structure, and a second dielectric material between the third and fourth interconnect structures, the second dielectric material including a second enclosed trench within a second space between the third and fourth interconnect structures.

Example 9 includes the IC package of example 8, further including transistors, and multiple additional interconnect layers closer to the transistors than the first and second interconnect layers are to the transistors.

Example 10 includes an integrated circuit (IC) package comprising a first interconnect structure and a second interconnect structure, and a dielectric structure positioned between the first and second interconnect structures, the dielectric structure defining a cavity substantially devoid of solid matter.

Example 11 includes the IC package of example 10, wherein the cavity occupies approximately half of a space between the first and second interconnect structures.

Example 12 includes the IC package of example 10, further including a package substrate, the first and second interconnect structures in the package substrate.

Example 13 includes the IC package of example 10, further including an interposer, the first and second interconnect structures in the interposer within the IC package.

Example 14 includes the IC package of example 10, further including a semiconductor die, the first and second interconnect structures in the semiconductor die within the IC package.

Example 15 includes the IC package of example 10, wherein the first and second interconnect structures are disposed on a first surface of an adjacent interconnect layer, the IC package further including a recess extending from the first surface into second dielectric material in the adjacent interconnect layer, the recess positioned between the first and second interconnect structures.

Example 16 includes the IC package of example 15, wherein the cavity of the dielectric structure extends into the recess.

Example 17 includes a method comprising providing, on a first surface of an underlying substrate, a first interconnect structure and a second interconnect structure adjacent to the first interconnect structure, a space disposed between the first and second interconnect structures, depositing a first portion of dielectric material on a first outer surface associated with the first interconnect structure and a second portion of the dielectric material on a second outer surface associated with the second interconnect structure, and generating an enclosed cavity within the space by connecting the first portion of the dielectric material with the second portion of the dielectric material, the first and second portions of the dielectric material defining overhangs over the space.

Example 18 includes the method of example 17, further including removing excess dielectric material above the enclosed cavity to generate a third surface.

Example 19 includes the method of example 18, wherein the space is a first space and the enclosed cavity is a first enclosed cavity, further including providing, on the third surface, a third interconnect structure and a fourth interconnect structure adjacent to the third interconnect structure, a second space disposed between the third and fourth interconnect structures, depositing a third portion of the dielectric material on a third outer surface of the third interconnect structure and a fourth portion of the dielectric material on a fourth outer surface on the fourth interconnect structure, and generating a second enclosed cavity within the second space by connecting the third portion of the dielectric material with the fourth portion of the dielectric material, the third and fourth portions of the dielectric material defining overhangs over the second space.

Example 20 includes the method of example 17, further including generating, prior to depositing the dielectric material, a recess that extends from the first surface into the underlying substrate, the recess positioned between the first interconnect structure and the second interconnect structure.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated circuit (IC) package comprising:
a first interconnect structure positioned on a first surface of an underlying substrate;
a second interconnect structure positioned on the first surface of the underlying substrate, the second interconnect structure adjacent to the first interconnect structure; and
a first dielectric material between the first and second interconnect structures, the first dielectric material including an enclosed trench within a space between the first and second interconnect structures.

2. The IC package of claim 1, wherein the enclosed trench includes a second dielectric material that is different than the first dielectric material.

3. The IC package of claim 1, wherein at least one of the first interconnect structure or the second interconnect structure is a trace.

4. The IC package of claim 1, wherein at least one of the first interconnect structure or the second interconnect structure is a via that extends through the first dielectric material.

5. The IC package of claim 1, wherein the first interconnect structure has a width and a height, the enclosed trench to extend away from the first surface of the underlying substrate beyond the height of the first interconnect structure.

6. The IC package of claim 1, wherein the enclosed trench includes a first portion and a second portion, the second portion having an arched cross-section.

7. The IC package of claim 1, wherein the first and second interconnect structures are in a first interconnect layer of the IC package, the first interconnect layer including a second surface facing away from the first surface of the underlying substrate.

8. The IC package of claim 7, wherein the space is a first space, the enclosed trench is a first enclosed trench, the IC package further including a second interconnect layer, the second interconnect layer including:
a third interconnect structure positioned on the second surface of the first interconnect layer;
a fourth interconnect structure positioned on the second surface of the first interconnect layer, the fourth interconnect structure adjacent to the third interconnect structure; and
a second dielectric material between the third and fourth interconnect structures, the second dielectric material including a second enclosed trench within a second space between the third and fourth interconnect structures.

9. The IC package of claim 8, further including:
transistors; and
multiple additional interconnect layers closer to the transistors than the first and second interconnect layers are to the transistors.

10. An integrated circuit (IC) package comprising:
a first interconnect structure and a second interconnect structure; and
a dielectric structure positioned between the first and second interconnect structures, the dielectric structure defining a cavity substantially devoid of solid matter.

11. The IC package of claim 10, wherein the cavity occupies approximately half of a space between the first and second interconnect structures.

12. The IC package of claim 10, further including a package substrate, the first and second interconnect structures in the package substrate.

13. The IC package of claim 10, further including an interposer, the first and second interconnect structures in the interposer within the IC package.

14. The IC package of claim 10, further including a semiconductor die, the first and second interconnect structures in the semiconductor die within the IC package.

15. The IC package of claim 10, wherein the first and second interconnect structures are disposed on a first surface of an adjacent interconnect layer, the IC package further including a recess extending from the first surface into second dielectric material in the adjacent interconnect layer, the recess positioned between the first and second interconnect structures.

16. The IC package of claim 15, wherein the cavity of the dielectric structure extends into the recess.

17. A method comprising:
providing, on a first surface of an underlying substrate, a first interconnect structure and a second interconnect structure adjacent to the first interconnect structure, a space disposed between the first and second interconnect structures;
depositing a first portion of dielectric material on a first outer surface associated with the first interconnect structure and a second portion of the dielectric material on a second outer surface associated with the second interconnect structure; and
generating an enclosed cavity within the space by connecting the first portion of the dielectric material with the second portion of the dielectric material, the first and second portions of the dielectric material defining overhangs over the space.

18. The method of claim 17, further including removing excess dielectric material above the enclosed cavity to generate a third surface.

19. The method of claim 18, wherein the space is a first space and the enclosed cavity is a first enclosed cavity, further including:
providing, on the third surface, a third interconnect structure and a fourth interconnect structure adjacent to the third interconnect structure, a second space disposed between the third and fourth interconnect structures;
depositing a third portion of the dielectric material on a third outer surface of the third interconnect structure and a fourth portion of the dielectric material on a fourth outer surface on the fourth interconnect structure; and
generating a second enclosed cavity within the second space by connecting the third portion of the dielectric material with the fourth portion of the dielectric material, the third and fourth portions of the dielectric material defining overhangs over the second space.

20. The method of claim 17, further including generating, prior to depositing the dielectric material, a recess that extends from the first surface into the underlying substrate, the recess positioned between the first interconnect structure and the second interconnect structure.
